(19) United States
(12) Patent Application Publication
(10) Pub. No.: US 2025/0147210 A1
(43) Pub. Date: May 8, 2025

(54) LIGHT ABSORPTION ANISOTROPIC FILM, MANUFACTURING METHOD OF LIGHT ABSORPTION ANISOTROPIC FILM, LAMINATE, AND IMAGE DISPLAY DEVICE

(71) Applicant: FUJIFILM Corporation, Tokyo (JP)

(72) Inventors: Rikako NAGAI, Kanagawa (JP); Yasukazu KUWAYAMA, Kanagawa (JP)

(73) Assignee: FUJIFILM Corporation, Tokyo (JP)

(21) Appl. No.: 19/013,631

(22) Filed: Jan. 8, 2025

Related U.S. Application Data
(63) Continuation of application No. PCT/JP2023/029538, filed on Aug. 15, 2023.

(30) Foreign Application Priority Data
Aug. 30, 2022 (JP) 2022-136971
Apr. 28, 2023 (JP) 2023-074758

(51) Int. Cl. G02B 5/22

(52) U.S. Cl. CPC G02B 5/22

(57) ABSTRACT

A light absorption anisotropic film, a manufacturing method of a light absorption anisotropic film, a laminate, and an image display device, in which, when a circularly polarizing plate combined with a λ/4 plate is applied to a display device and the display device is brought into a black display state, black density is excellent. The light absorption anisotropic film contains a liquid crystal compound, and a dichroic substance. The dichroic substance forms an associate, and when, in a cross section of the light absorption anisotropic film observed with a scanning transmission electron microscope, 100 associates are selected, a number of associates B in which a length of a major axis is 30 nm or more and less than 60 nm is denoted by Nb, and a number of associates C in which a length of a major axis is 60 nm or more is denoted by Nc, Nb>Nc.

### CROSS-REFERENCE TO RELATED APPLICATIONS

This application is a Continuation of PCT International Application No. PCT/JP2023/029538 filed on Aug. 15, 2023, which was published under PCT Article 21 (2) in Japanese, and which claims priority under 35 U.S.C. § 119 (a) to Japanese Patent Application No. 2022-136971 filed on Aug. 30, 2022 and Japanese Patent Application No. 2023-074758 filed on Apr. 28, 2023. The above applications are hereby expressly incorporated by reference, in their entirety, into the present application.

### BACKGROUND OF THE INVENTION

### 1. Field of the Invention

The present invention relates to a light absorption anisotropic film, a manufacturing method of a light absorption anisotropic film, a laminate, and an image display device.

### 2. Description of the Related Art

An optically anisotropic layer having a phase difference, such as a λ/4 plate, is used in a wide variety of applications. For example, since an organic electroluminescence (EL) display device among image display devices has a structure using metal electrodes, external light may be reflected, resulting in problems of contrast reduction and reflected glare. Therefore, in the related art, a polarizing plate including the optically anisotropic layer and a polarizer (light absorption anisotropic film) has been used in order to suppress the adverse effect of external light reflection.

WO2022/054556A discloses a circularly polarizing plate in which a polarizer (light absorption anisotropic film) containing a liquid crystal compound and a dichroic substance and an optically anisotropic layer (λ/4 plate) containing a liquid crystal compound are bonded to each other.

### SUMMARY OF THE INVENTION

In recent years, in an image display device, it is required to improve black density in order to further improve image quality. The term “black density” means that, in a case where the image display device is brought into a black display state, black tinting is suppressed and reflectivity of reflected light is low.

The present inventors have found that there is room for improvement in black density in a case where a display device obtained by using the circularly polarizing plate as disclosed in WO2022/054556A is set to black display and a display screen is irradiated with visible light.

An object of the present invention is to provide a light absorption anisotropic film, a manufacturing method of a light absorption anisotropic film, a laminate, and an image display device, in which, in a case where a circularly polarizing plate combined with a λ/4 plate is applied to a display device and the display device is brought into a black display state, black density is excellent.

As a result of intensive studies on the problems in the related art, the present inventors have found that the above-described objects can be accomplished by the following configurations.

[1]

A light absorption anisotropic film comprising:
a liquid crystal compound; and
a dichroic substance,
in which the dichroic substance forms an associate, and
in a case where, in a cross section of the light absorption anisotropic film observed with a scanning transmission electron microscope, 100 of the associates are selected, a number of associates B in which a length of a major axis is 30 nm or more and less than 60 nm is denoted by Nb, and a number of associates C in which a length of a major axis is 60 nm or more is denoted by Nc, a relationship between Nb and Nc satisfies the following expression (1),

$$Nb > Nc . \qquad ( 1 )$$

[2]

The light absorption anisotropic film according to [1],
in which the relationship between Nb and Nc satisfies the following expression (2),

$$0.5 \times Nb > Nc . \qquad ( 2 )$$

[3]

The light absorption anisotropic film according to [1] or [2],
in which, in a case where, in a cross section of the light absorption anisotropic film observed with a scanning transmission electron microscope, 100 of the associates are selected, a number of associates A in which a length of a major axis is less than 30 nm is denoted by Na, Na is 35 or less.
   [4]

The light absorption anisotropic film according to any one of [1] to [3],
in which a concentration of the dichroic substance in the light absorption anisotropic film is 180 mg/cm³ or more.
   [5]

The light absorption anisotropic film according to any one of [1] to [4], in which an absolute value of a difference between a log P value of the liquid crystal compound and a log P value of the dichroic substance is 4.1 or more.

[6]

A manufacturing method of the light absorption anisotropic film according to any one of [1] to [5], comprising:
a coating film-forming step of forming a coating film by applying a composition containing a liquid crystal compound, a dichroic substance, and a solvent;
a first heating step of heating the coating film at a temperature higher than a melting point of the dichroic substance;
a cooling step of cooling the coating film subjected to the first heating step; and
a second heating step of heating the coating film subjected to the cooling step at a temperature lower than a phase transition temperature of the liquid crystal compound from a crystal state to a liquid crystal state by 15° C. or higher.
   [7]

A laminate comprising:
a base material; and
the light absorption anisotropic film according to any one of [1] to [5], disposed on the base material.
   [8]

The laminate according to [7], further comprising:
a λ/4 plate provided on the light absorption anisotropic film.
   [9]

An image display device comprising:
the light absorption anisotropic film according to any one of [1] to [5].
   [10]

An image display device comprising:
the laminate according to [7] or [8].

According to the present invention, it is possible to provide a light absorption anisotropic film, a manufacturing method of a light absorption anisotropic film, a laminate, and an image display device, in which, in a case where a circularly polarizing plate combined with a λ/4 plate is applied to a display device and the display device is brought into a black display state, black density is excellent.

### BRIEF DESCRIPTION OF THE DRAWINGS

FIG. 1 is a conceptual view showing an example of a state in which a first dichroic substance and a second dichroic substance form an associate.

FIG. 2 is a conceptual view showing an example of the associate of the first dichroic substance and the second dichroic substance.

FIG. 3 is a view conceptually showing an example of a cross section of a light absorption anisotropic film according to an embodiment of the present invention.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

In the present specification, numerical ranges represented by “to” include numerical values before and after “to” as lower limit values and upper limit values. In a numerical range described in a stepwise manner in the present specification, an upper limit value or a lower limit value described in a certain numerical range may be replaced with an upper limit value or a lower limit value in another numerical range described in a stepwise manner. In addition, in the numerical range described in the present specification, an upper limit value and a lower limit value described in a certain numerical range may be replaced with values shown in Examples.

In addition, in the present specification, parallel, orthogonal, horizontal, and vertical do not indicate parallel, orthogonal, horizontal, and vertical in a strict sense, but respectively indicate a range of parallel±10°, a range of orthogonal±10°, a range of horizontal±10°, and a range of vertical±10°.

In addition, in the present specification, substances corresponding to respective components may be used alone or in combination of two or more kinds thereof. Here, in a case where two or more kinds of substances corresponding to respective components are used in combination, the content of the components indicates the total content of the substances used in combination unless otherwise specified.

In addition, in the present specification, a combination of two or more preferred aspects is a more preferred aspect.

In addition, in the present specification, “(meth)acrylate” denotes “acrylate” or “methacrylate”, “(meth)acryl” denotes “acryl” or “methacryl”, “(meth)acryloyl” denotes “acryloyl” or “methacryloyl”, and “(meth)acrylic acid” denotes “acrylic acid” or “methacrylic acid”.

### [Light Absorption Anisotropic Film]

The light absorption anisotropic film according to the embodiment of the present invention contains a liquid crystal compound and a dichroic substance, in which the dichroic substance forms an associate, and in a case where, in a cross section of the light absorption anisotropic film observed with a scanning transmission electron microscope, 100 of the associates are selected, a number of associates B in which a length of a major axis is 30 nm or more and less than 60 nm is denoted by Nb, and a number of associates C in which a length of a major axis is 60 nm or more is denoted by Nc, a relationship between Nb and Nc satisfies the following expression (1).

$$Nb > Nc \qquad ( 1 )$$

The present inventors have conducted studies focusing on a relationship between a size of the associate contained in the light absorption anisotropic film and black density of a display device, and as a result, have found that a display device having an excellent black density can be obtained by satisfying the relationship of expression (1). Details of the reason for this are not clear, but it is presumed that the number of associates having a large size (the number Nc of the associates C) which are likely to cause light scattering is smaller than the number Nb of the associates B, and thus the light scattering is suppressed and the black density of the display device is improved.

### [Associate]

In the light absorption anisotropic film according to the embodiment of the present invention, the dichroic substance forms an associate.

Here, the associate refers to a state in which, in the light absorption anisotropic film, the dichroic substances are collected to form an aggregate and molecules of the dichroic substances are periodically arranged in the aggregate.

In addition, the associate may be composed of only the dichroic substance, or may be composed of the liquid crystal compound and the dichroic substance.

In addition, the associate may be composed of one kind of dichroic substance, or may be composed of a plurality of kinds of dichroic substances.

In addition, an associate composed of a certain kind of dichroic substance and an associate composed of another kind of dichroic substance may coexist in the light absorption anisotropic film.

In addition, in a case where the light absorption anisotropic film contains a plurality of kinds of dichroic substances, among the plurality of kinds of dichroic substances contained in the light absorption anisotropic film, all of the plurality of kinds of dichroic substances may form the associate, or some kinds of dichroic substances may form the associate.

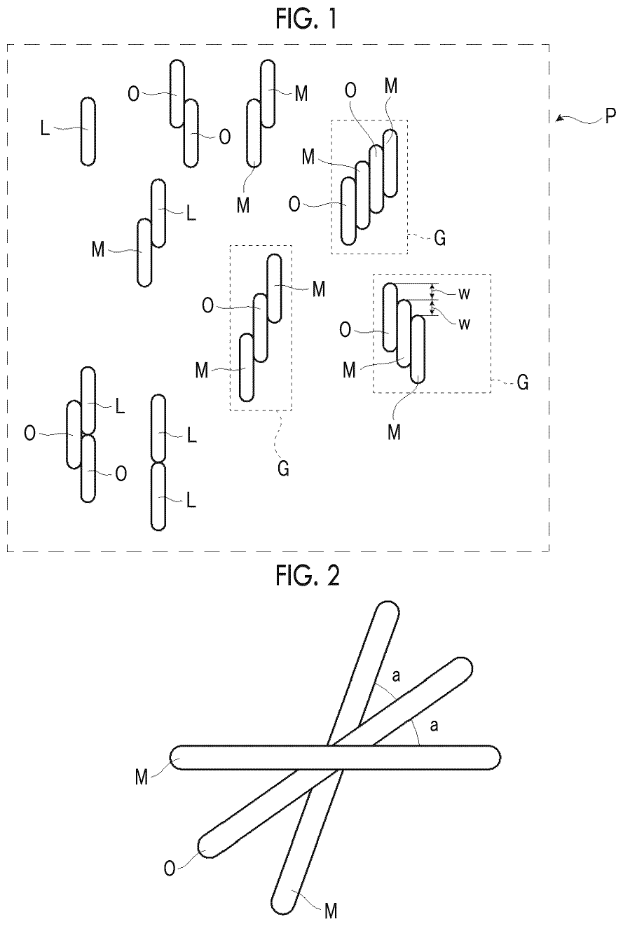

FIG. 1 is a conceptual view showing an example of a state in which a first dichroic substance and a second dichroic substance form the associate. A light absorption anisotropic film P has a molecule M of a first dichroic substance, a molecule O of a second dichroic substance, and a molecule L of a liquid crystal compound. As shown in FIG. 1, an aggregate G having the molecule M and the molecule O is formed, major axis directions of the molecule M and the molecule O are aligned along the same direction in the aggregate G, and the molecule M and the molecule O are arranged so as to be shifted in a period of a width w.

The associate formed of the first dichroic substance and the second dichroic substance is not limited to the associate in FIG. 1, and for example, as shown in FIG. 2, the molecule M and the molecule O may be arranged such that the molecules M and O deviate from each other by an angle a in a periodic manner.

In FIGS. 1 and 2, the first dichroic substance and the second dichroic substance may be dichroic substances of the same type or dichroic substances of different types.

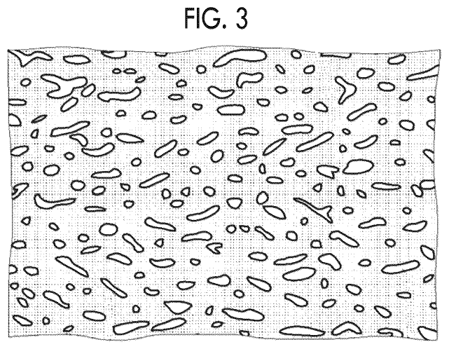

FIG. 3 is a view conceptually showing a cross section of an example of the light absorption anisotropic film according to the embodiment of the present invention. In FIG. 3, a portion shown in white in the drawing is the associate.

Examples of a verification method of the formation of the associate of the dichroic substance include a method of comparing a maximum absorption wavelength measured using the formed film with a maximum absorption wavelength of the solution.

Specific examples of the method of measuring the maximum absorption wavelength using the formed film include a method of producing a film in which a thick film (10 μm or more) is vertically aligned, cutting the film, and measuring an absorption spectrum of the cross section of the film with a device such as MSV-5200 (manufactured by JASCO Corporation).

In addition, examples of another method of measuring the maximum absorption wavelength using the formed film include a method of producing a film formed by the same method as that for forming the light absorption anisotropic film according to the embodiment of the present invention using a composition for forming the light absorption anisotropic film according to the embodiment of the present invention, except that the composition is not aligned, and measuring the absorption spectrum of the film. Examples of the method of not aligning the composition for forming the light absorption anisotropic film include a method of controlling the alignment by the presence or absence of an alignment agent or an interface improver and the adjustment of the amount thereof, or the presence or absence of an alignment film or a change in the alignment film, which will be described later.

Here, the maximum absorption wavelength of the solution is considered to be the maximum absorption wavelength in a state in which the dichroic substance is present alone (there is no interaction between the dichroic substances) in a case where the solution is a sufficiently diluted solution.

On the other hand, in a case where the maximum absorption wavelength measured using the film is different from the maximum absorption wavelength of the solution, it is considered that the dichroic substance interacts with other substances (that is, forms the associate).

Specifically, a maximum absorption wavelength As in an absorption spectrum of a solution in which the dichroic substance is dissolved is determined. In this case, a concentration of the diluted solution is preferably 3.0% or less and more preferably 2.0% or less.

Next, a composition containing at least a liquid crystal compound and a dichroic substance is cast on a substrate (for example, blue plate glass), and the cast composition is subjected to heat aging and curing by ultraviolet irradiation in the same manner as the light absorption anisotropic film according to the embodiment of the present invention to form a film F for measuring a maximum absorption wavelength. Next, an absorption spectrum of the film F is measured at a pitch of 0.5 nm in a wavelength range of 380 to 800 nm, and a maximum absorption wavelength λf is obtained.

In a case where λs and λf described above satisfy the following expression (D), it can be seen that the dichroic substance forms an associate for the following reason.

$$\vert λ s - λ f \vert \geq 2. nm ( D )$$

That is, since the absorption spectrum of the solution in which the dichroic substance is dissolved is understood as the absorption spectrum of one molecule of the dichroic substance, in a case where the maximum absorption wavelength As of the absorption spectrum and the maximum absorption wavelength λf of the absorption spectrum of the film F satisfy the expression (D), it can be said that the maximum absorption wavelength is shifted due to the association of the dichroic substance in the film F.

In the present invention, the cross section is observed with a scanning transmission electron microscope (hereinafter, also abbreviated as “STEM”) as follows.

First, an ultra-thin section of the light absorption anisotropic film, having a thickness of 100 nm in a film thickness direction, is produced using an ultramicrotome.

Next, the ultra-thin section is placed on a grid with a carbon support film for STEM observation.

Thereafter, the grid is placed in the scanning transmission electron microscope, and the cross section is observed at an electron beam acceleration voltage of 30 kV.

In addition, a length L of a major axis and a length D of a minor axis of the associate are specifically measured as follows.

First, as described above, the cross section of the light absorption anisotropic film is observed with STEM, a captured image is analyzed to create a frequency histogram, and a frequency at which the frequency is maximized and a standard deviation of a frequency distribution are acquired. Next, a frequency at which the frequency is 1.3 times the standard deviation on a dark side from the frequency at which the frequency is maximized is set as a threshold value. Next, in image in which the brightness is binarized is created using the threshold value, and a portion having a major axis of 10 nm or more in the binarized dark region is extracted as the associate.

Furthermore, each of the extracted associates is approximated to an ellipse, a length of a major axis of the approximated ellipse is defined as the length L of the major axis of the associate, and a length of a minor axis of the approximated ellipse is defined as the length D of the minor axis of the associate. In addition, an angle formed by an axis perpendicular to the film surface (normal direction of the light absorption anisotropic film) and a major axis of an approximate ellipse is defined as an angle formed by the major axis of the associate and the normal direction of the light absorption anisotropic film.

The length L of the major axis and the length D of the minor axis of the associate may be measured using known image processing software. Examples of the image processing software include image processing software “ImageJ”.

In the light absorption anisotropic film according to the embodiment of the present invention, in a case where any 100 associates are selected from associates present in an image obtained by analyzing a cross-sectional image captured by STEM, it is preferable that a relationship between the number Nb of associates B in which the length L of the major axis is 30 nm or more and less than 60 nm and the number Nc of associates C in which the length L of the major axis is 60 nm or more satisfies the following expression (1); and from the viewpoint that the black density of the image display device is more excellent, it is preferable that the relationship satisfies the following expression (2).

$$Nb > Nc \qquad ( 1 )$$

$$0.5 \times Nb > Nc \qquad ( 2 )$$

Specifically, the image analysis is performed as described above, and any 100 associates satisfying L≥10 nm are selected in three regions (a total of 40 μm²) of 13.58 μm², which are randomly selected and do not overlap with each other. In a case where the number of associates satisfying L≥10 nm in three regions (total of 40 μm²) is less than 100, the selection of aggregates satisfying L≥10 nm is further performed from other regions (13.58 μm² per region) until the number of associates becomes 100.

The number of such associates is counted in 10 randomly selected regions of 40 μm² (13.58 μm²×3), which do not overlap each other, and the number of the associates B and the number of the associates C are counted for each region. In addition, an average value of the number of the associates B and an average value of the number of the associates C at the 10 regions where the measurement is performed are calculated, and these average values are respectively set as the number Nb of the associates B and the number Nc of the associates C.

It is noted that the measurement is actually performed in a region of 13.58 μm²×3=40.74 μm², but in the present invention, the number of digits is rounded down and “per 40 μm²” is used for convenience.

From the viewpoint that the black density of the image display device is more excellent, the number Nb of the associates B is preferably 50 or more, and more preferably 60 or more.

The upper limit of the number Nb of the associates B is not particularly limited, but is usually 100 or less, and in many cases, 99 or less, and further, in many cases, 90 or less.

From the viewpoint that the black density of the image display device is more excellent, the number Nc of the associates C is preferably 40 or less, and more preferably 20 or less.

Examples of a method of adjusting the number Nb and the number Nc for satisfying the expression (1) include a method of adopting the manufacturing method of a light absorption anisotropic film, which will be described later.

In addition, examples of a method of adjusting the number Nb and the number Nc for satisfying the expression (2) include using a dichroic substance and a liquid crystal composition, satisfying Δlog P described later, and adjusting a concentration of the dichroic substance in the light absorption anisotropic film to be in a range described later.

In the light absorption anisotropic film according to the embodiment of the present invention, in a case where any 100 associates are selected from associates present in an image obtained by analyzing a cross-sectional image captured by STEM, a number Na of associates A in which the length L of the major axis is less than 30 nm is preferably 35 or less, and more preferably less than 20. In a case where the number Na of the associates A is 35 or less, heat resistance is excellent.

The number Na of the associates A is obtained by the same method as the number Nb of the associates B and the number Nc of the associates C described above, except that the number of associates having the length L of the major axis of less than 30 nm is counted.

Examples of the method of adjusting the number Na to the above-described range include a method of adopting the manufacturing method of a light absorption anisotropic film, which will be described later, using a dichroic substance and a liquid crystal composition, satisfying Δlog P described later, and adjusting a concentration of the dichroic substance in the light absorption anisotropic film to be in a range described later. In addition, the number Na can be adjusted depending on a heating temperature in the manufacturing method of a light absorption anisotropic film, which will be described later, and for example, the value of the number Na decreases as the second heating temperature increases.

### [Liquid Crystal Compound]

The light absorption anisotropic film according to the embodiment of the present invention contains a liquid crystal compound. In this manner, the dichroic substance can be aligned with a high alignment degree while precipitation of the dichroic substance is restrained.

As the liquid crystal compound, both a high-molecular-weight liquid crystal compound and a low-molecular-weight liquid crystal compound can be used, and from the viewpoint of increasing the alignment degree, a high-molecular-weight liquid crystal compound is preferable. In addition, the high-molecular-weight liquid crystal compound and the low-molecular-weight liquid crystal compound may be used in combination as the liquid crystal compound.

Here, the “high-molecular-weight liquid crystal compound” refers to a liquid crystal compound having a repeating unit in the chemical structure.

In addition, the “low-molecular-weight liquid crystal compound” refers to a liquid crystal compound having no repeating unit in the chemical structure.

Examples of the high-molecular-weight liquid crystal compound include thermotropic liquid crystalline polymers described in JP2011-237513A and high-molecular-weight liquid crystal compounds described in paragraphs to of WO2018/199096A.

Examples of the low-molecular-weight liquid crystal compound include liquid crystal compounds described in paragraphs to of JP2013-228706A, and among these, a liquid crystal compound exhibiting smectic properties is preferable.

Examples of such a liquid crystal compound include compounds described in paragraphs [0019] to [0140] of WO2022/014340A, the description of which is incorporated herein by reference.

From the viewpoint that the effect of the present invention is more excellent, a content of the liquid crystal compound is preferably 50% to 99% by mass and more preferably 65% to 85% by mass with respect to the total mass of the light absorption anisotropic film.

A log P value of the liquid crystal compound is preferably 3.5 to 8.5 and more preferably 4.5 to 7.5.

Here, the log P value is an index for expressing properties of hydrophilicity and hydrophobicity of a chemical structure, and is also referred to as a hydrophilic-hydrophobic parameter. The log P value of each compound in the present specification can be calculated using software such as Chem Bio Draw Ultra or HSPiP (Ver. 4.1.07). In addition, the log P value can be acquired experimentally by the method of the OECD Guidelines for the Testing of Chemicals, Sections 1, Test No. 117, or the like. In the present invention, a value calculated by inputting the structural formula of a compound to HSPiP (Ver. 4.1.07) is adopted as the log P value unless otherwise specified.

### [Dichroic Substance]

The light absorption anisotropic film according to the embodiment of the present invention contains a dichroic substance.

The dichroic substance is preferably a dichroic azo coloring agent compound, and a dichroic azo coloring agent compound used for a so-called coating-type polarizer can be used. The dichroic azo coloring agent compound is not particularly limited, and known dichroic azo coloring agents in the related art can be used, but compounds described below are preferably used.

The dichroic substance may be polymerized in the light absorption anisotropic film.

In the present invention, the dichroic azo coloring agent compound means a coloring agent having different absorbances depending on directions.

The dichroic azo coloring agent compound may or may not exhibit liquid crystallinity.

In a case where the dichroic azo coloring agent compound exhibits liquid crystallinity, any of nematic properties or smectic properties may be exhibited. A temperature range at which the liquid crystal phase is exhibited is preferably room temperature (approximately 20° C. to 28° C.) to 300° C., and from the viewpoint of handleability and manufacturing suitability, more preferably 50° C. to 200° C.

In the present invention, from the viewpoint of adjusting tint, the light absorption anisotropic film contains preferably at least one coloring agent compound having a maximal absorption wavelength in a wavelength range of 560 to 700 nm (hereinafter, also abbreviated as “first dichroic azo coloring agent compound”) and at least one coloring agent compound having a maximal absorption wavelength in a wavelength range of 455 nm or more and less than 560 nm (hereinafter, also abbreviated as “second dichroic azo coloring agent compound”), and specifically, it is more preferable to contain at least a dichroic azo coloring agent compound represented by Formula (1) and a dichroic azo coloring agent compound represented by Formula (2).

In the present invention, three or more kinds of dichroic azo coloring agent compounds may be used in combination. For example, from the viewpoint of making color of the light absorption anisotropic film close to black, it is preferable to use the first dichroic azo coloring agent compound, the second dichroic azo coloring agent compound, and at least one coloring agent compound having a maximal absorption wavelength in a wavelength range of 380 nm or more and less than 455 nm (preferably in a wavelength range of 380 to 454 nm) (hereinafter, also abbreviated as “third dichroic azo coloring agent compound”) in combination.

In the present invention, from the reason of improving pressing resistance, it is preferable that the dichroic azo coloring agent compound has a crosslinkable group.

Specific examples of the crosslinkable group include a (meth)acryloyl group, an epoxy group, an oxetanyl group, and a styryl group, and among these, a (meth)acryloyl group is preferable.

### <First Dichroic Azo Coloring Agent Compound>

It is preferable that the first dichroic azo coloring agent compound is a compound having a chromophore which is a nucleus and a side chain bonded to a terminal of the chromophore.

Specific examples of the chromophore include an aromatic ring group (such as an aromatic hydrocarbon group and an aromatic heterocyclic group) and an azo group, and a structure having both the aromatic ring group and the azo group is preferable, and a bisazo structure having the aromatic heterocyclic group (preferably a thienothiazole group) and two azo groups is more preferable.

The side chain is not particularly limited, and examples thereof include a group represented by L3, R2, or L4 in Formula (1) described later.

From the viewpoint adjusting the tint of the light absorption anisotropic film, it is preferable that the first dichroic azo coloring agent compound is a dichroic azo coloring agent compound having a maximum absorption wavelength in a wavelength range of 560 nm or more and 700 nm or less (more preferably in a range of 560 to 650 nm and still more preferably in a range of 560 to 640 nm).

The maximum absorption wavelength (nm) of the dichroic azo coloring agent compound in the present specification is acquired from an ultraviolet visible spectrum in a wavelength range of 380 to 800 nm, which is measured with a spectrophotometer using a solution prepared by dissolving the dichroic azo coloring agent compound in a good solvent.

In the present invention, from the viewpoint of further improving the alignment degree of the light absorption anisotropic film to be formed, it is preferable that the first dichroic azo coloring agent compound is a compound represented by Formula (1).

In addition, in a case where the dichroic substance includes the compound represented by Formula (1), the alignment degree of the light absorption anisotropic film is more excellent due to the presumed reason that an interaction between the first dichroic azo coloring agents and an interaction between the first dichroic azo coloring agent and the liquid crystal compound are enhanced.

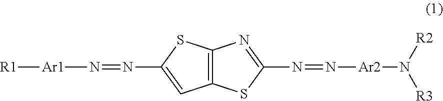

In Formula (1), Ar1 and Ar2 each independently represent a phenylene group which may have a substituent or a naphthylene group which may have a substituent, and a phenylene group is preferable.

In Formula (1), R1 represents a hydrogen atom, or an alkyl group, an alkoxy group, an alkylthio group, an alkylsulfonyl group, an alkylcarbonyl group, an alkyloxycarbonyl group, an acyloxy group, an alkylcarbonate group, an alkylamino group, an acylamino group, an alkylcarbonylamino group, an alkoxycarbonylamino group, an alkylsulfonylamino group, an alkylsulfamoyl group, an alkylcarbamoyl group, an alkylsulfinyl group, an alkylureido group, an alkylphosphoric acid amide group, an alkylimino group, or an alkylsilyl group, each of which may have a substituent.

In a case where R1 is a group containing a carbon atom, the number of carbon atoms in R1 is preferably 1 or more, more preferably 3 or more, and still more preferably 5 or more, and from the viewpoint of further improving the alignment degree, particularly preferably 9 or more and most preferably 10 or more.

In a case where R1 is a group containing a carbon atom, the number of carbon atoms in R1 is preferably 20 or less, more preferably 18 or less, and still more preferably 15 or less.

In a case where R1 is an alkyl group or a group containing an alkyl group, the alkyl group may be linear or branched.

In a case where R1 is an alkyl group, —CH₂— in the alkyl group may be substituted with a divalent substituent such as —O—, —CO—, —C(O)—O—, —O—C(O)—, —Si(CH₃)₂—O—Si(CH₃)₂—, —N(R1′)-, —N(R1′)-CO—, —CO—N(R1′)-, —N(R1′)-C(O)—O—, —O—C(O)—N(R1′)-, —N(R1′)-C(O)—N(R1′)-, —CH═CH—, —C≡C—, —N═N—, —C(R1′)=CH—C(O)—, or —O—C(O)—O—; and among these divalent substituents, —O—, —CO—, —C(O)—O—, or —O—C(O)— is preferable.

In a case where R1 is a group other than a hydrogen atom, specific examples of the substituent (monovalent substituent) which can be contained in each group are as described later; but among those, an acyl group, an acyloxy group, a halogen atom, a nitro group, a cyano group, —N(R1′)₂, an amino group, —C(R1′)=C(R1′)-NO₂, —C(R1′)=C(R1′)-CN, or —C(R1′)=C(CN)₂ is preferable.

R1′ represents a hydrogen atom or a linear or branched alkyl group having 1 to 6 carbon atoms. In a case where a plurality of (R1′)'s are present in each group, these may be the same or different from each other.

In Formula (1), R2 and R3 each independently represent a hydrogen atom, or an alkyl group, an alkoxy group, an acyl group, an alkyloxycarbonyl group, an alkylamide group, an alkylsulfonyl group, an aryl group, an arylcarbonyl group, an arylsulfonyl group, an aryloxycarbonyl group, or an arylamide group, each of which may have a substituent.

In a case where R2 or R3 is an alkyl group, —CH₂— in the alkyl group may be substituted with a divalent substituent such as —O—, —S—, —C(O)—, —C(O)—O—, —O—C(O)—, —C(O)—S—, —S—C(O)—, —Si(CH₃)₂—O—Si(CH₃)₂—, —NR2′-, —NR2′-CO—, —CO—NR2′-, —NR2′-C(O)—O—, —O—C(O)—NR2′-, —NR2′-C(O)—NR2′-, —CH═CH—, —C═C—, —N═N—, —C(R2′)=CH—C(O)—, and —O—C(O)—O—.

In a case where R2 and R3 are groups other than a hydrogen atom, specific examples of the substituent (monovalent substituent) which can be contained in each group are as described later; but among those, a halogen atom, a nitro group, a cyano group, a hydroxy group, —N(R2′)₂, an amino group, —C(R2′)-C(R2′)-NO₂, —C(R2′)=C(R2′)-CN, or —C(R2′)=C(CN)₂ is preferable.

R2′ represents a hydrogen atom or a linear or branched alkyl group having 1 to 6 carbon atoms. In a case where a plurality of (R2′)'s are present in each group, these may be the same or different from each other.

R2 and R3 may be bonded to each other to form a ring, or R2 or R3 may be bonded to Ar2 to form a ring.

From the viewpoint of light resistance, it is preferable that R1 represents an electron-withdrawing group and R2 and R3 represent a group having a low electron-donating property.

Specific examples of R1 in such a group include an alkylsulfonyl group, an alkylcarbonyl group, an alkyloxycarbonyl group, an acyloxy group, an alkylsulfonylamino group, an alkylsulfamoyl group, an alkylsulfinyl group, and an alkylureido group, and examples of R2 and R3 in such a group include groups having the following structures. The groups having the following structures are shown in a form having a nitrogen atom to which R2 and R3 are bonded in Formula (1).

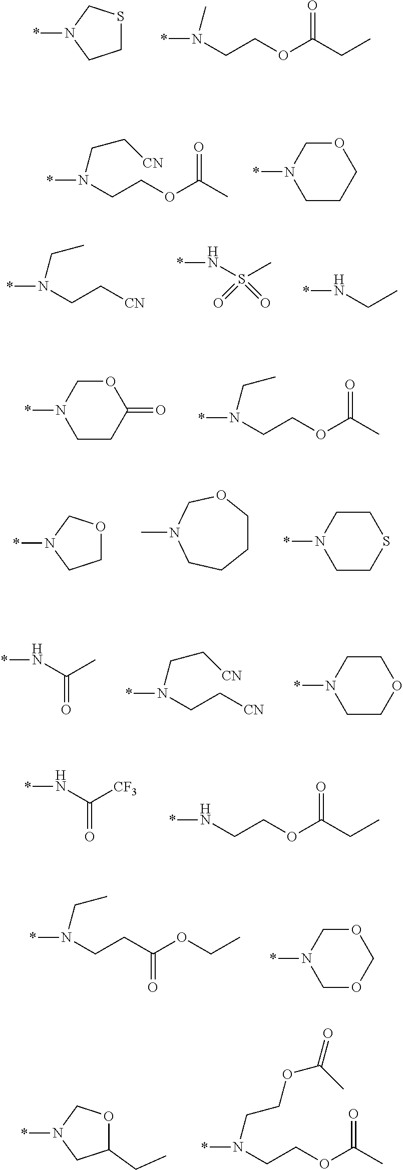

Specific examples of the first dichroic azo coloring agent compound are shown below, but the present invention is not limited thereto.

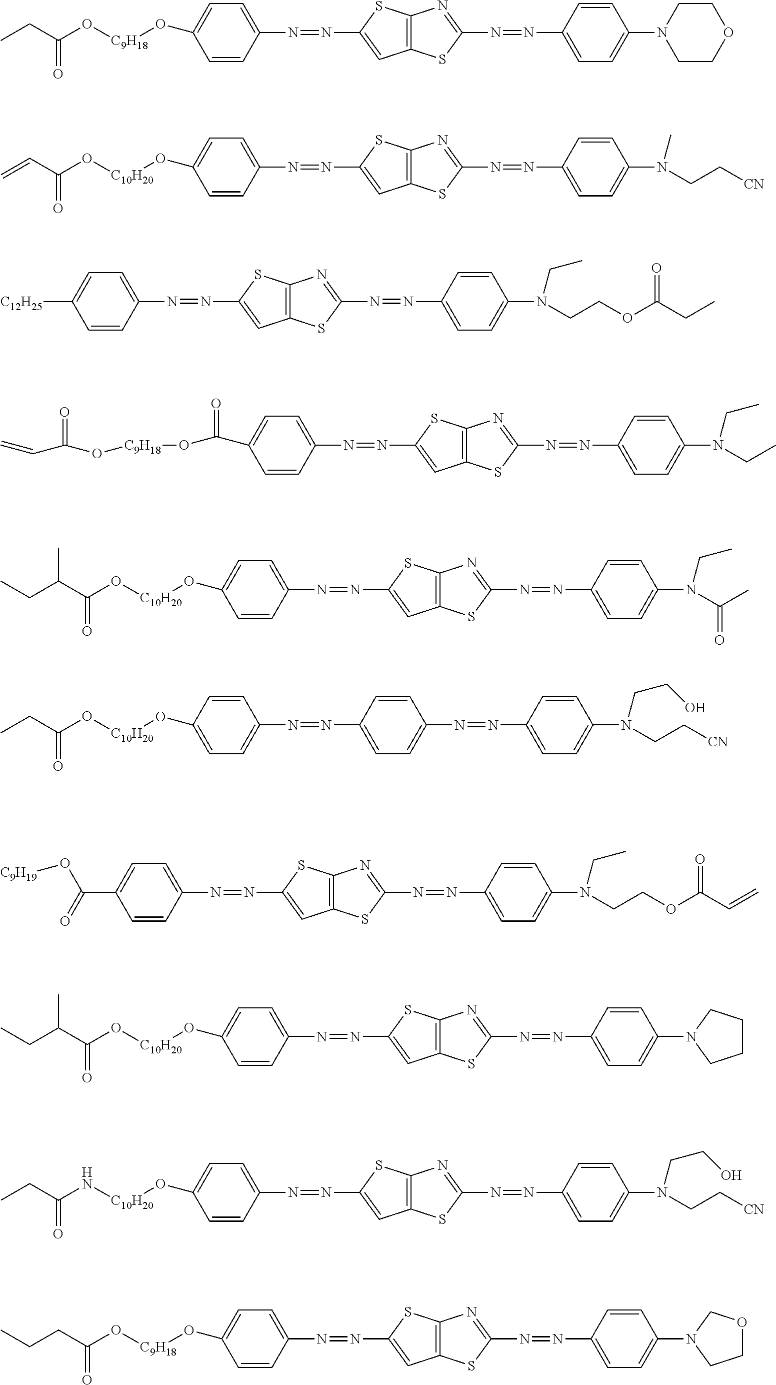

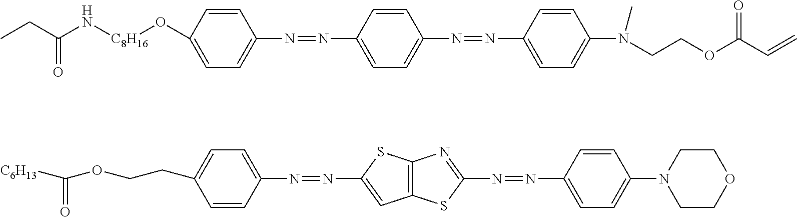

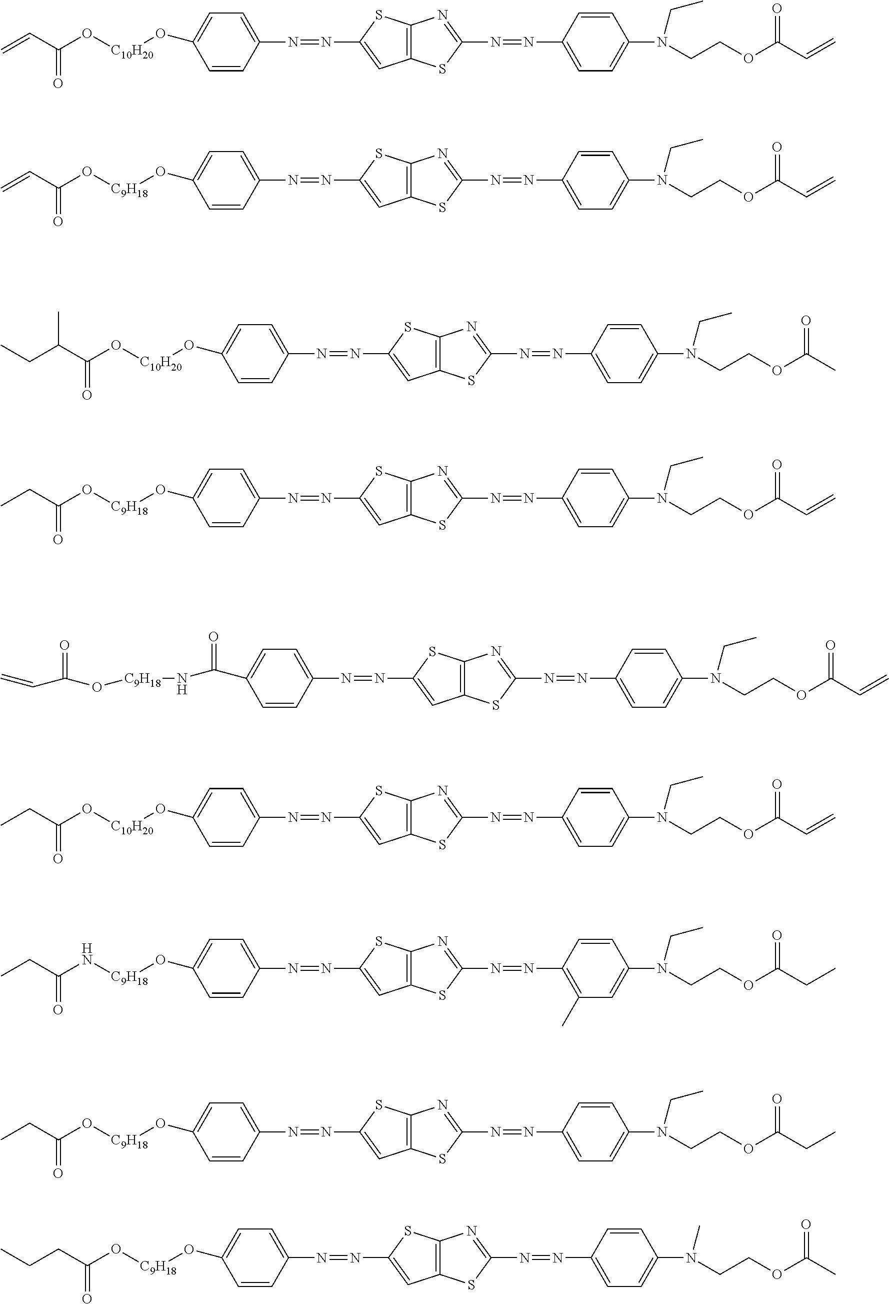

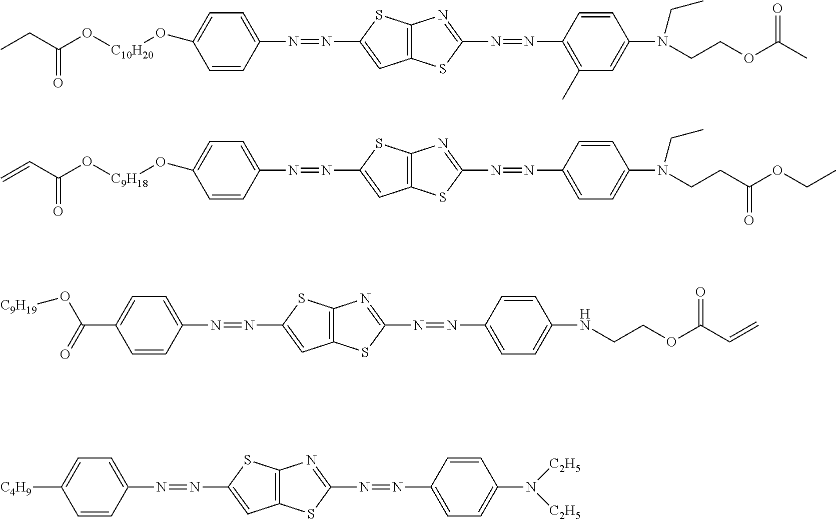

### <Second Dichroic Azo Coloring Agent Compound>

The second dichroic azo coloring agent compound is a compound different from the first dichroic azo coloring agent compound, and specifically, a chemical structure thereof is different from that of the first dichroic azo coloring agent compound.

It is preferable that the second dichroic azo coloring agent compound is a compound having a chromophore which is a nucleus of a dichroic azo coloring agent compound and a side chain bonded to a terminal of the chromophore.

Specific examples of the chromophore include an aromatic ring group (such as an aromatic hydrocarbon group and an aromatic heterocyclic group) and an azo group; and a structure having both the aromatic hydrocarbon group and the azo group is preferable, and a trisazo structure having the aromatic hydrocarbon group and two or three azo groups is more preferable.

The side chain is not particularly limited, and examples thereof include a group represented by R4, R5, or R6 in Formula (2) described later.

The second dichroic azo coloring agent compound is a dichroic azo coloring agent compound having a maximum absorption wavelength in a wavelength range of 455 nm or more and less than 560 nm, and from the viewpoint of adjusting the tint of the light absorption anisotropic film, it is preferably a dichroic azo coloring agent compound having a maximum absorption wavelength in a wavelength range of 455 to 555 nm and more preferably a dichroic azo coloring agent compound having a maximum absorption wavelength in a wavelength range of 455 to 550 nm.

In particular, the tint of the light absorption anisotropic film is easily adjusted by using the first dichroic azo coloring agent compound having a maximum absorption wavelength of 560 to 700 nm and the second dichroic azo coloring agent compound having a maximum absorption wavelength of 455 nm or more and less than 560 nm.

From the viewpoint of further improving the alignment degree of the light absorption anisotropic film, it is preferable that the second dichroic azo coloring agent compound is a compound represented by Formula (2).

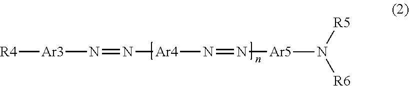

In Formula (2), n represents 1 or 2.

In Formula (2), Ar3, Ar4, and Ar5 each independently represent a phenylene group which may have a substituent, a naphthylene group which may have a substituent, or a heterocyclic group which may have a substituent.

The heterocyclic group may be aromatic or non-aromatic.

Examples of atoms other than carbon, constituting the aromatic heterocyclic group, include a nitrogen atom, a sulfur atom, and an oxygen atom. In a case where the aromatic heterocyclic group has a plurality of atoms other than carbon, constituting a ring, these atoms may be the same or different from each other.

Specific examples of the aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

In Formula (2), R4 has the same definition as that for R1 in Formula (1).

In Formula (2), R5 and R6 each have the same definition as that for R2 and R3 in Formula (1).

From the viewpoint of light resistance, it is preferable that R4 represents an electron-withdrawing group and R5 and R6 represent a group having a low electron-donating property.

Among such groups, specific examples of the case where R4 represents an electron-withdrawing group are the same as the specific examples of the case where R1 represents an electron-withdrawing group; and specific examples of the case where R5 and R6 represent a group having a low electron-donating property are the same as the specific examples of the case where R2 and R3 represent a group having a low electron-donating property.

Specific examples of the second dichroic azo coloring agent compound are shown below, but the present invention is not limited thereto.

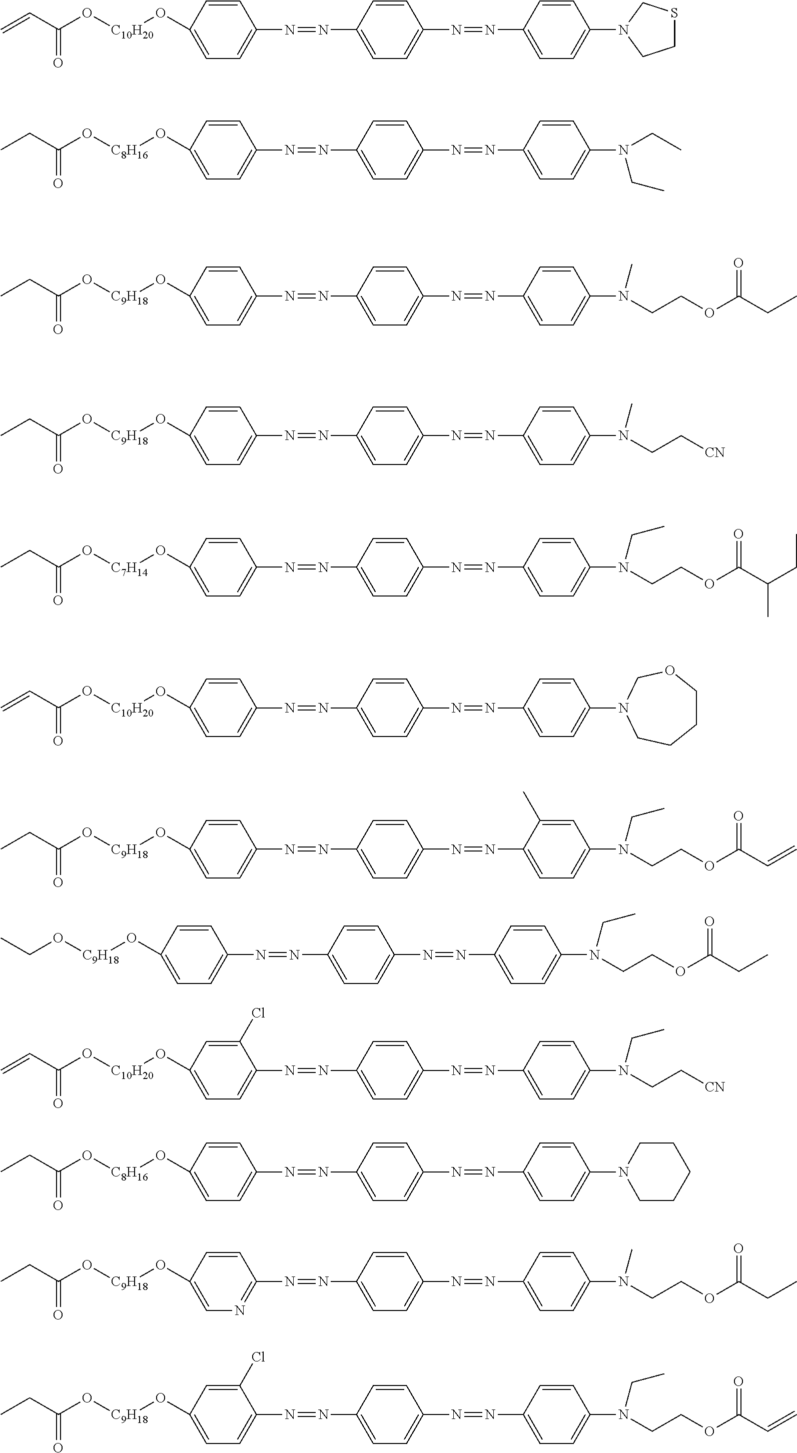

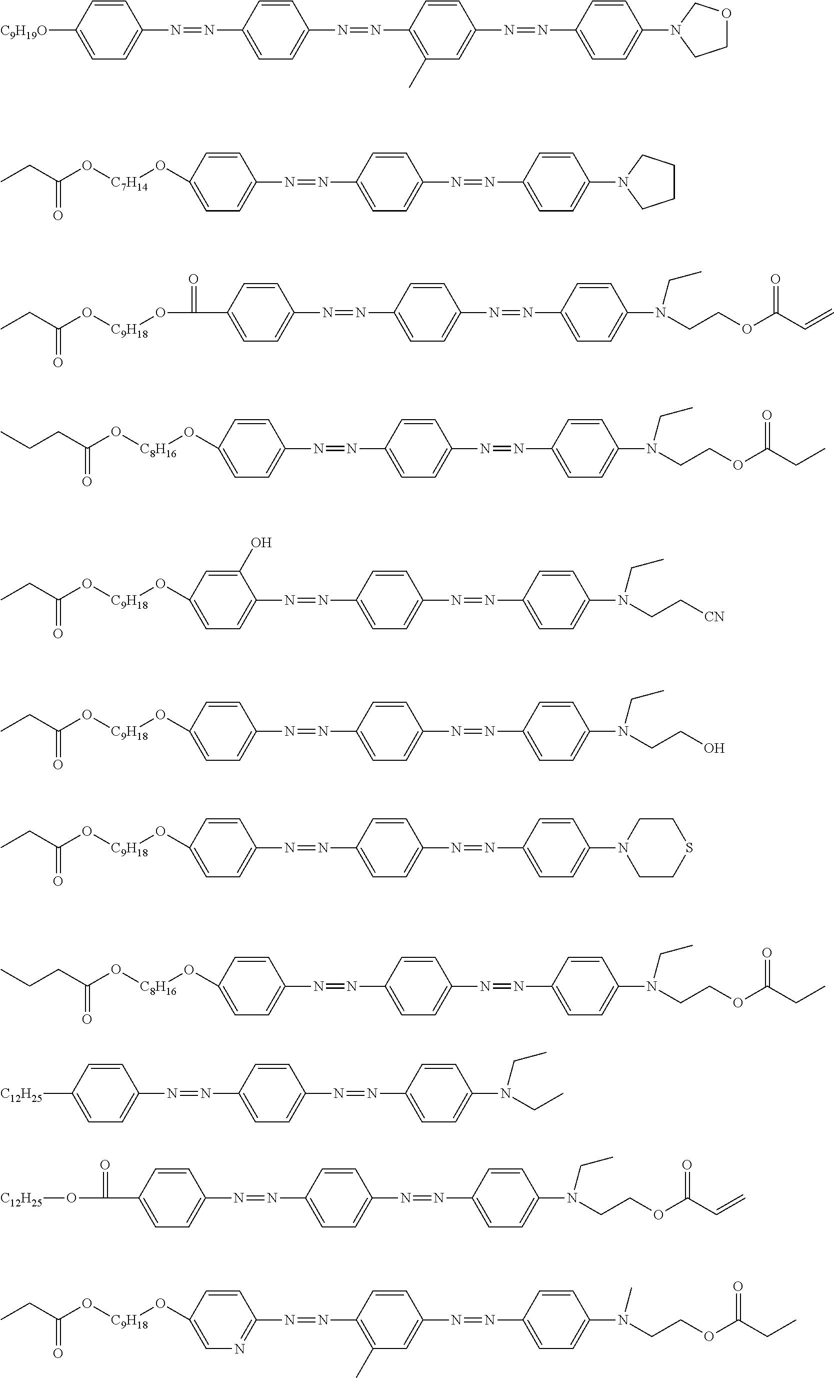

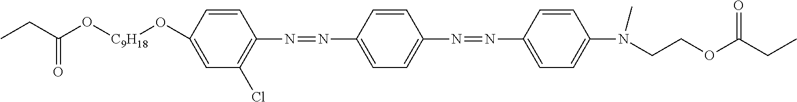

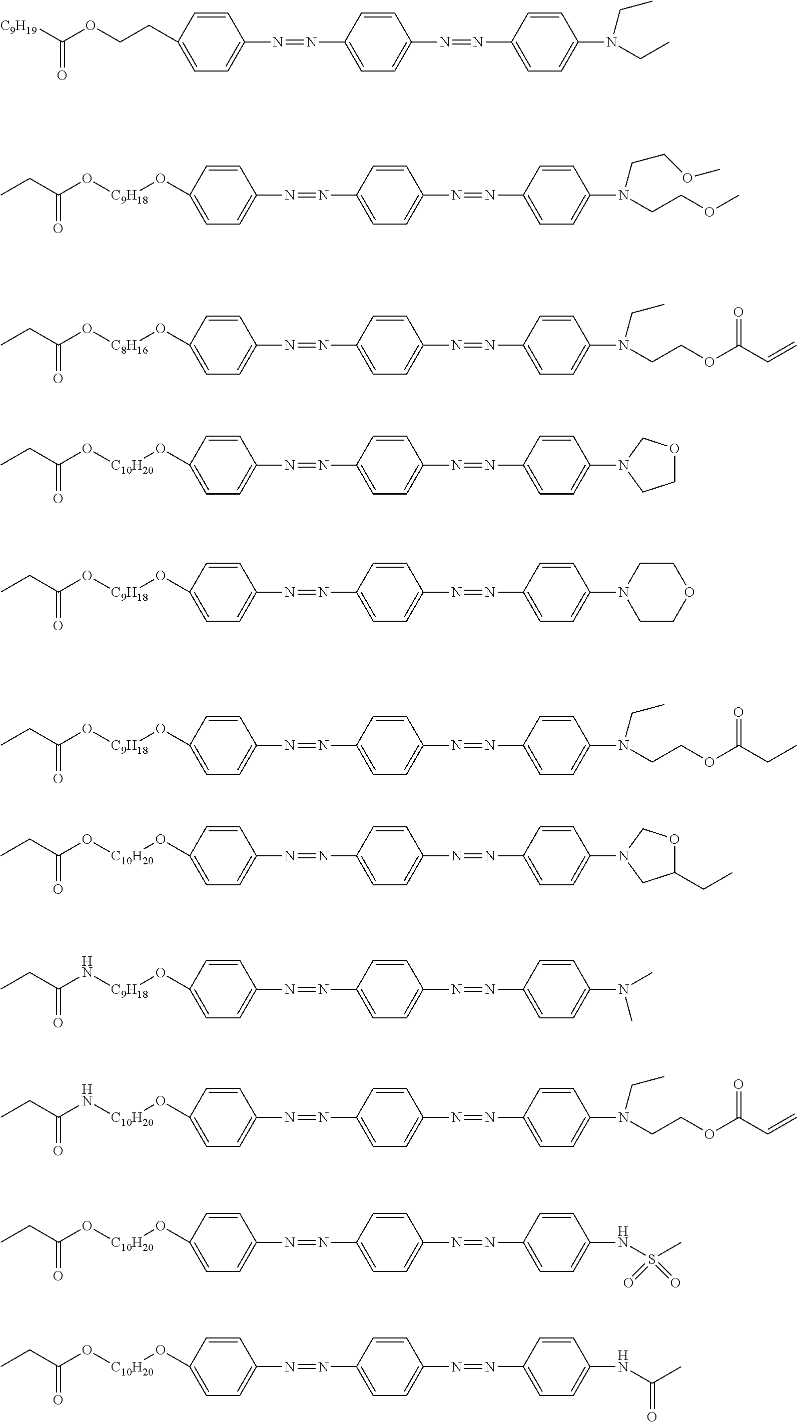

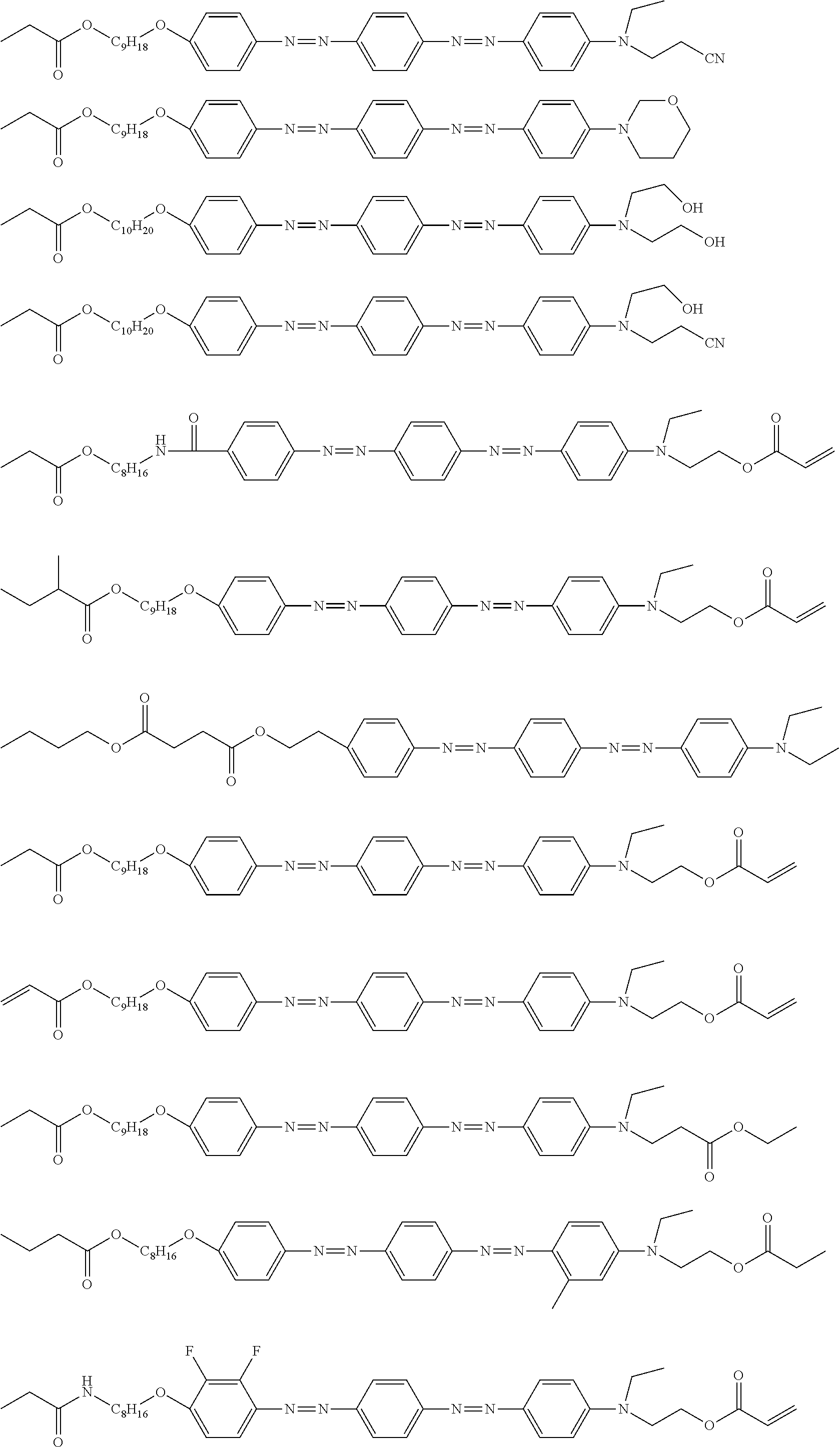

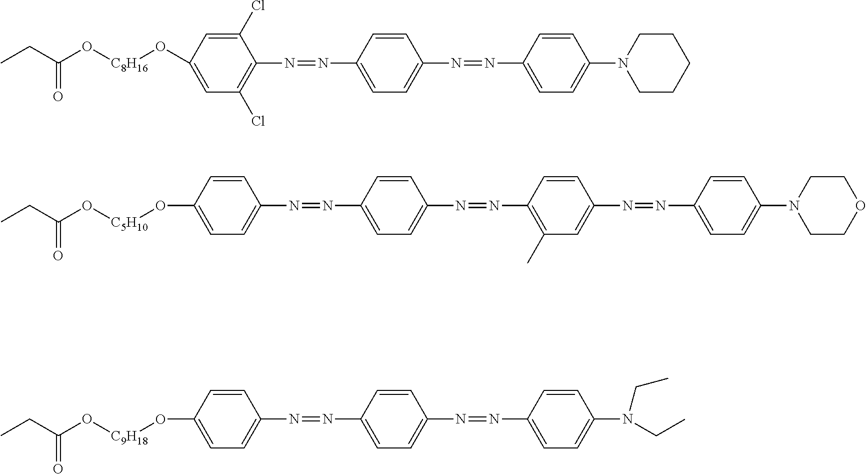

### <Third Dichroic Azo Coloring Agent Compound>

The third dichroic azo coloring agent compound is a dichroic azo coloring agent compound other than the first dichroic azo coloring agent compound and the second dichroic azo coloring agent compound, and specifically, a chemical structure thereof is different from those of the first dichroic azo coloring agent compound and the second dichroic azo coloring agent compound. In a case where the light absorption anisotropic film contains the third dichroic azo coloring agent compound, there is an advantage that the tint of the light absorption anisotropic film is easily adjusted.

The maximum absorption wavelength of the third dichroic azo coloring agent compound is 380 nm or more and less than 455 nm, preferably 385 to 454 nm.

Specific examples of the third dichroic azo coloring agent compound include compounds other than the first dichroic azo coloring agent compound and the second dichroic azo coloring agent compound described above among compounds represented by Formula (1) described in WO2017/195833A.

Specific examples of the third dichroic azo coloring agent compound are shown below, but the present invention is not limited thereto. In the following specific examples, n represents an integer of 1 to 10. In addition, Me represents a methyl group.

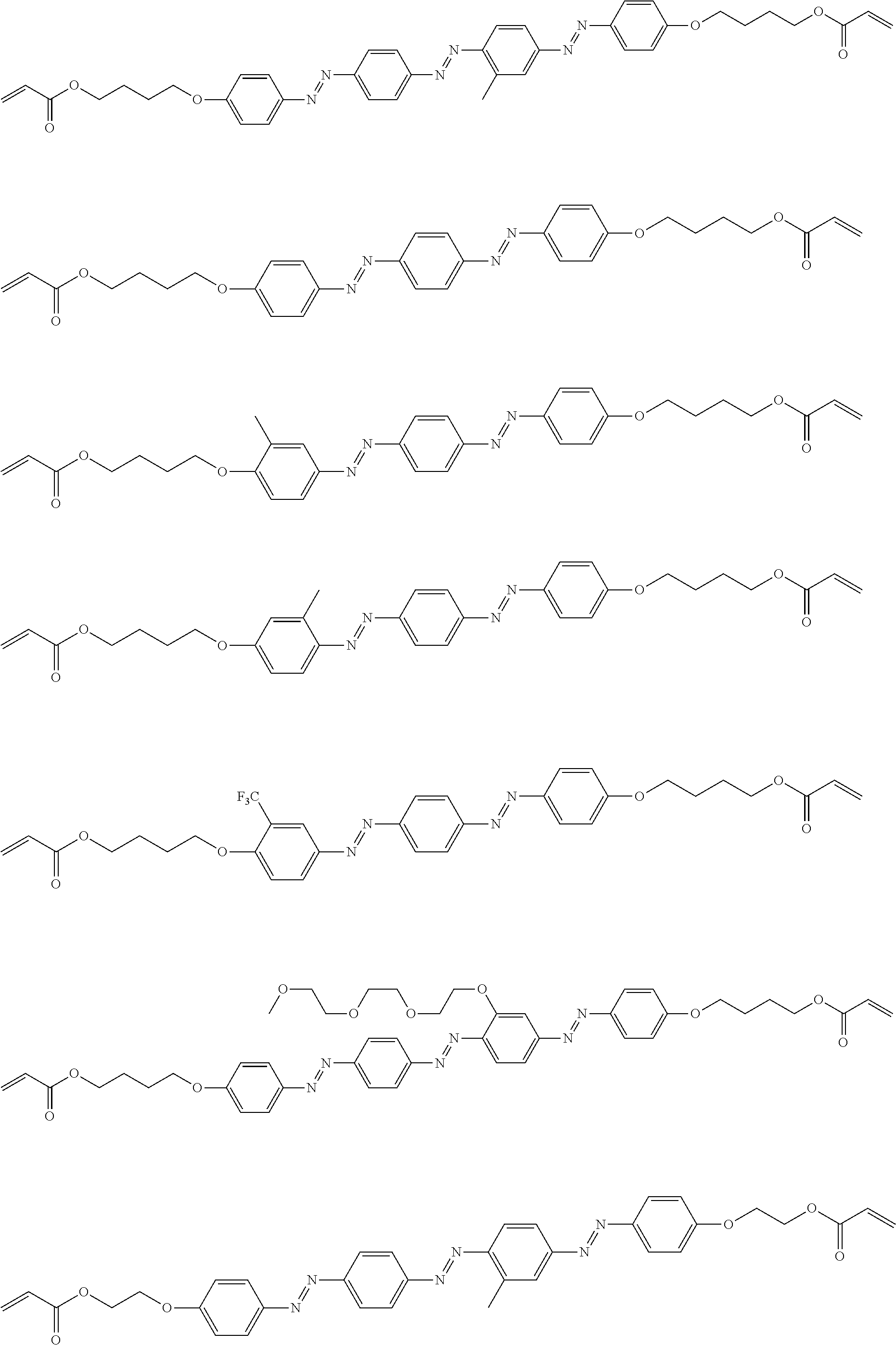

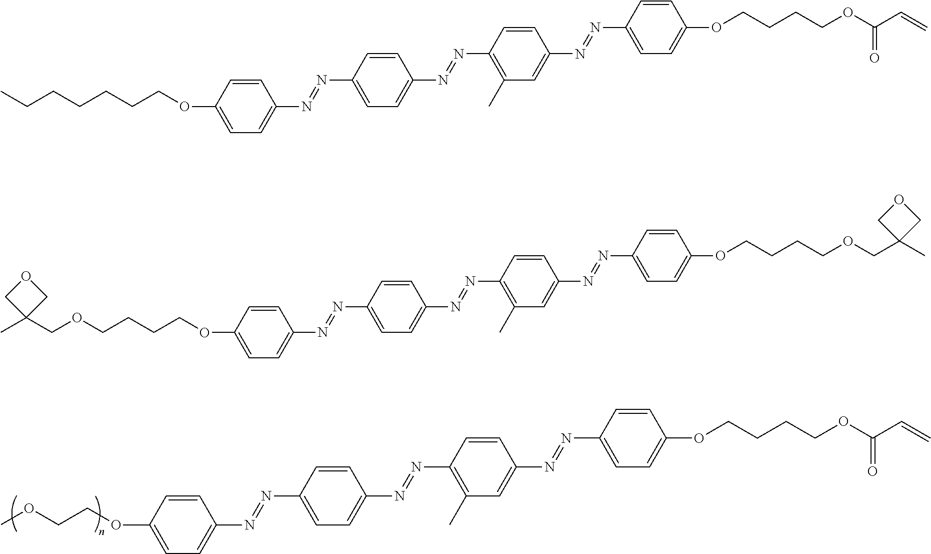

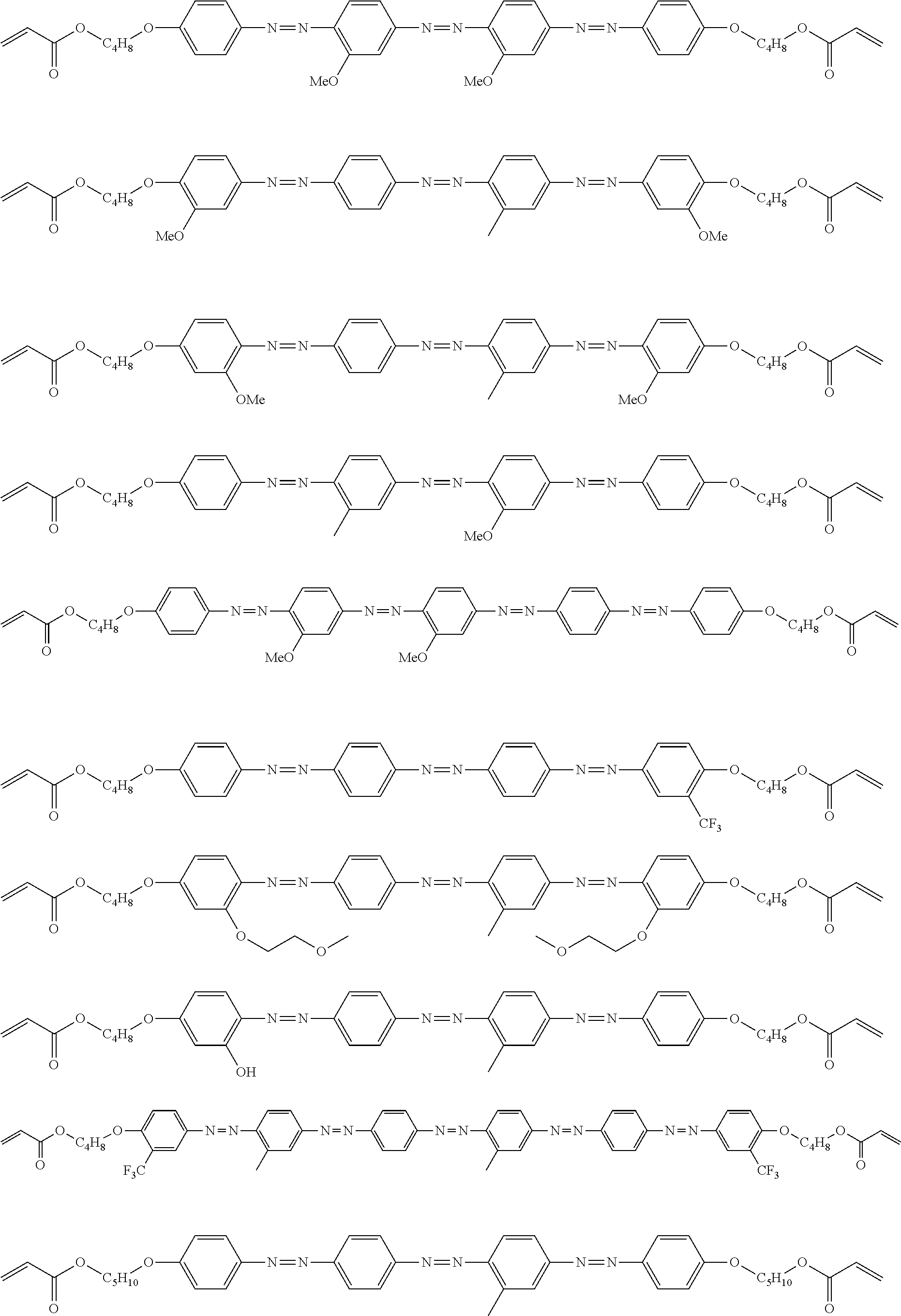

### <Content of Dichroic Substance>

A concentration of the dichroic substance in the light absorption anisotropic film is preferably 170 mg/cm³ or more, more preferably 180 mg/cm³ or more, and still more preferably 240 mg/cm³ or more.

In a case where the concentration of the dichroic substance is 180 mg/cm³ or more, the number Nb of the associates B in which the length of the major axis is 30 nm or more and less than 60 nm can be made larger than the number Nc of the associates C in which the length of the major axis is 60 nm or more. The details of the reason for this are not clear, but it is presumed to be due to the following reason. For example, in a case where the content of the dichroic substance in the composition used for forming the light absorption anisotropic film is large, it is considered that the number of nuclei for forming the associate of the dichroic substance increases during the formation of the light absorption anisotropic film. It is presumed that, in a case where the number of nuclei in the film is large as described above, the number of molecules of the dichroic substance which is not used for forming the nuclei is small, and thus the increase in the size of the associate is suppressed, and as a result, the number of associates having a small size, such as the associates B, is increased.

The concentration of the dichroic substance in the light absorption anisotropic film is preferably 500 mg/cm₃ or less, more preferably 400 mg/cm₃ or less, and still more preferably 300 mg/cm₃ or less. In a case where the concentration of the dichroic substance is 500 mg/cm₃ or less, precipitation of the coloring agent in the film can be suppressed.

Here, the concentration of the dichroic substance in the light absorption anisotropic film is determined by measuring a solution obtained by dissolving the light absorption anisotropic film or an extraction liquid obtained by immersing the light absorption anisotropic film in a solvent, by high performance liquid chromatography (HPLC). The quantification can be performed using the dichroic substance contained in the light absorption anisotropic film as a standard sample.

In a case where HPLC measurement is performed using a laminate including the light absorption anisotropic film, the concentration of the dichroic substance in the light absorption anisotropic film can be calculated as follows. First, a volume is calculated by multiplying a thickness of the light absorption anisotropic film obtained from the image of the cross section of the laminate observed with a microscope by the area of the laminate used for the measurement of HPLC. Next, the concentration of the dichroic substance in the light absorption anisotropic film can be obtained by dividing the mass of the dichroic substance measured by HPLC by the obtained volume.

A content of the dichroic substance is preferably 17% to 50% by mass and more preferably 23% to 30% by mass with respect to the total mass of the light absorption anisotropic film.

A content of the first dichroic azo coloring agent compound is preferably 40 to 90 parts by mass and more preferably 45 to 85 parts by mass with respect to 100 parts by mass of the total content of the dichroic substance in the light absorption anisotropic film.

A content of the second dichroic azo coloring agent compound is preferably 4 to 50 parts by mass and more preferably 5 to 35 parts by mass with respect to 100 parts by mass of the total content of the dichroic substance in the light absorption anisotropic film.

A content of the third dichroic azo coloring agent compound is preferably 1 to 50 parts by mass and more preferably 2 to 40 parts by mass with respect to 100 parts by mass of the total content of the dichroic substance in the light absorption anisotropic film.

A content ratio between the first dichroic azo coloring agent compound, the second dichroic azo coloring agent compound, and the third dichroic azo coloring agent compound used as necessary can be optionally set in order to adjust the tint of the light absorption anisotropic film. However, the content ratio of the second dichroic azo coloring agent compound to the first dichroic azo coloring agent compound (second dichroic azo coloring agent compound/first dichroic azo coloring agent compound) is preferably 0.1 to 10, more preferably 0.2 to 5, and still more preferably 0.3 to 0.8 in terms of moles. In a case where the content ratio of the second dichroic azo coloring agent compound to the first dichroic azo coloring agent compound is within the above-described range, the alignment degree is increased.

### <Log P Value>

An absolute value of a difference between a log P value of the liquid crystal compound and a log P value of the dichroic substance (hereinafter, also referred to as “Δlog P”) is preferably 4.1 or more, more preferably 5.1 or more, and still more preferably 6.1 or more.

In a case where the Δlog Pis 4.1 or more, the number Nb of the associates B in which the length of the major axis is 30 nm or more and less than 60 nm can be made larger than the number Nc of the associates C in which the length of the major axis is 60 nm or more. The details of the reason for this are not clear, but it is presumed to be due to the following reason. It is considered that, in a case where the difference between the log P value of the liquid crystal compound and the log P value of the dichroic substance is large, the compatibility of both components is lowered, and thus the generation of nuclei for forming the associate of the dichroic substance is promoted. It is considered that, in a case where the generation of nuclei in the film is promoted and the number of nuclei is increased, the number of molecules of the dichroic substance which is not used for the formation of nuclei in the film is decreased. As a result, it is presumed that the increase in the size of the associate is suppressed, and thus the number of associates having a small size, such as the associates B, is increased.

From the viewpoint of solubility, the Δlog Pis preferably 9.0 or less, more preferably 8.0 or less, and still more preferably 7.0 or less.

In a case where the light absorption anisotropic film contains a plurality of dichroic substances or liquid crystal compounds, it is sufficient that the maximum value of the absolute value of the difference calculated from the log P value of the dichroic substance and the log P value of the liquid crystal compound satisfies the value of Δlog P, but it is preferable that all the values satisfy the above value from the viewpoint that the black density is more excellent.

A log P value of the dichroic substance is preferably 8 to 13, more preferably 8.5 to 12.5, and still more preferably 9 to 12.

The method of measuring the log P value of the dichroic substance is as described above.

### [Other Components]

The light absorption anisotropic film according to the embodiment of the present invention may contain a component other than the liquid crystal compound and the dichroic substance (hereinafter, also referred to as “other components”).

Specific examples of the other components include an interface improver.

### <Interface Improver>

The light absorption anisotropic film according to the embodiment of the present invention preferably contains an interface improver (hereinafter, also referred to as “surfactant”). In a case where the light absorption anisotropic film according to the embodiment of the present invention contains an interface improver, smoothness of a coated surface is improved, the alignment degree is improved, and cissing and unevenness are suppressed so that in-plane uniformity is expected to be improved.

As the interface improver, interface improvers which allow liquid crystal compounds to be horizontally aligned are preferable, and compounds (horizontal alignment agents) described in paragraphs [0253] to [0293] of JP2011-237513A can be used. In addition, fluorine (meth)acrylate-based polymers described in [0018] to [0043] of JP2007-272185A can also be used. A compound other than the compounds described above may be used as the interface improver. The interface improver may be used alone or in combination of two or more kinds thereof.

A weight-average molecular weight of the interface improver is preferably 5,000 to 30,000 and more preferably 5,000 to 17,500.

In a case where the light absorption anisotropic film contains an interface improver, a content of the interface improver is preferably 0.1% to 2.0% by mass and more preferably 0.1% to 1.0% by mass with respect to the total mass of the light absorption anisotropic film.

Here, the weight-average molecular weight in the present invention is a value measured by gel permeation chromatography (GPC) under the following conditions.
Solvent (eluent): N-methylpyrrolidone
Device name: TOSOH HLC-8220GPC
Column: using three columns of TOSOH TSKgel Super AWM-H (6 mm×15 cm) connected
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2,800,000 to 1,050 (Mw/Mn=1.03 to 1.06) are used

### [Substituent]

The substituent (monovalent substituent) in the present specification denotes the following groups unless otherwise specified.

Examples of the substituent include an alkyl group (preferably an alkyl group having 1 to 20 carbon atoms, more preferably an alkyl group having 1 to 12 carbon atoms, and still more preferably an alkyl group having 1 to 8 carbon atoms; examples thereof a methyl group, an ethyl group, an isopropyl group, a tert-butyl group, an n-octyl group, an n-decyl group, an n-hexadecyl group, a cyclopropyl group, a cyclopentyl group, and a cyclohexyl group);
an alkenyl group (preferably an alkenyl group having 2 to 20 carbon atoms, more preferably an alkenyl group having 2 to 12 carbon atoms, and still preferably an alkenyl group having 2 to 8 carbon atoms; examples thereof include a vinyl group, an aryl group, a 2-butenyl group, and a 3-pentenyl group);
an alkynyl group (preferably an alkynyl group having 2 to 20 carbon atoms, more preferably an alkynyl group 2 to 12 carbon atoms, and still more preferably an alkynyl group having 2 to 8 carbon atoms; examples thereof include a propargyl group and a 3-pentynyl group);
an aryl group (preferably an aryl group having 6 to 30 carbon atoms, more preferably an aryl group having 6 to 20 carbon atoms, and still more preferably an aryl group having 6 to 12 carbon atoms; examples thereof include a phenyl group, a 2,6-diethylphenyl group, a 3,5-ditrifluoromethylphenyl group, a styryl group, a naphthyl group, and a biphenyl group);
a substituted or unsubstituted amino group (preferably an amino group having 0 to 20 carbon atoms, more preferably an amino group having 0 to 10 carbon atoms, and still more preferably an amino group having 0 to 6 carbon atoms; examples thereof include an unsubstituted amino group, a methylamino group, a dimethylamino group, a diethylamino group, and an anilino group);
an alkoxy group (preferably an alkoxy group having 1 to 20 carbon atoms and more preferably an alkoxy group having 1 to 15 carbon atoms; examples thereof include a methoxy group, an ethoxy group, and a butoxy group);
an oxycarbonyl group (preferably an oxycarbonyl group having 2 to 20 carbon atoms, more preferably an oxycarbonyl group having 2 to 15 carbon atoms, and still more preferably an oxycarbonyl group having 2 to 10 carbon atoms; examples thereof include a methoxycarbonyl group, an ethoxycarbonyl group, and a phenoxycarbonyl group);
an acyl group (preferably an acyl group having 1 to 48 carbon atoms and more preferably an acyl group having 1 to 24 carbon atoms, such as a formyl group, an acetyl group, an acryloyl group, a methacryloyl group, a pivaloyl group, a benzoyl group, a tetradecanoyl group, and a cyclohexanoyl group);
an acyloxy group (preferably an acyloxy group having 2 to 20 carbon atoms, more preferably an acyloxy group having 2 to 10 carbon atoms, and still more preferably an acyloxy group having 2 to 6 carbon atoms; examples thereof include an acetoxy group, a benzoyloxy group, an acryloyloxy group, and a methacryloyloxy group);
an acylamino group (preferably an acylamino group having 2 to 20 carbon atoms, more preferably an acylamino group having 2 to 10 carbon atoms, and still more preferably an acylamino group having 2 to 6 carbon atoms; examples thereof include an acetylamino group and a benzoylamino group);
an alkoxycarbonylamino group (preferably an alkoxycarbonylamino group having 2 to 20 carbon atoms, more preferably an alkoxycarbonylamino group having 2 to 10 carbon atoms, and still more preferably an alkoxycarbonylamino group having 2 to 6 carbon atoms; examples thereof include a methoxycarbonylamino group);
an aryloxycarbonylamino group (preferably an aryloxycarbonylamino group having 7 to 20 carbon atoms, more preferably an aryloxycarbonylamino group having 7 to 16 carbon atoms, and still more preferably an aryloxycarbonylamino group having 7 to 12 carbon atoms; examples thereof include a phenyloxycarbonylamino group);
a sulfonylamino group (preferably a sulfonylamino group having 1 to 20 carbon atoms, more preferably a sulfonylamino group having 1 to 10 carbon atoms, and still more preferably a sulfonylamino group having 1 to 6 carbon atoms; examples thereof include a methanesulfonylamino group and a benzenesulfonylamino group);
a sulfamoyl group (preferably a sulfamoyl group having 0 to 20 carbon atoms, more preferably a sulfamoyl group having 0 to 10 carbon atoms, and still more preferably a sulfamoyl group having 0 to 6 carbon atoms; examples thereof include a sulfamoyl group, a methylsulfamoyl group, a dimethylsulfamoyl group, and a phenylsulfamoyl group);
a carbamoyl group (preferably a carbamoyl group having 1 to 20 carbon atoms, more preferably a carbamoyl group having 1 to 10 carbon atoms, and still more preferably a carbamoyl group having 1 to 6 carbon atoms; examples thereof include an unsubstituted carbamoyl group, a methylcarbamoyl group, a diethylcarbamoyl group, and a phenylcarbamoyl group);
an alkylthio group (preferably an alkylthio group having 1 to 20 carbon atoms, more preferably an alkylthio group having 1 to 10 carbon atoms, and still more preferably an alkylthio group having 1 to 6 carbon atoms; examples thereof include a methylthio group and an ethylthio group);
an arylthio group (preferably an arylthio group having 6 to 20 carbon atoms, more preferably an arylthio group having 6 to 16 carbon atoms, and still more preferably an arylthio group having 6 to 12 carbon atoms; examples thereof include a phenylthio group);
a sulfonyl group (preferably a sulfonyl group having 1 to 20 carbon atoms, more preferably a sulfonyl group having 1 to 10 carbon atoms, and still more preferably a sulfonyl group having 1 to 6 carbon atoms; examples thereof include a mesyl group and a tosyl group);
a sulfinyl group (preferably a sulfinyl group having 1 to 20 carbon atoms, more preferably a sulfinyl group having 1 to 10 carbon atoms, and still more preferably a sulfinyl group having 1 to 6 carbon atoms; examples thereof include a methanesulfinyl group and a benzenesulfinyl group);
a ureido group (preferably a ureido group having 1 to 20 carbon atoms, more preferably a ureido group having 1 to 10 carbon atoms, and still more preferably a ureido group having 1 to 6 carbon atoms; examples thereof include an unsubstituted ureido group, a methylureido group, and a phenylureido group);
a phosphoric acid amide group (preferably a phosphoric acid amide group having 1 to 20 carbon atoms, more preferably a phosphoric acid amide group having 1 to 10 carbon atoms, and still more preferably a phosphoric acid amide group having 1 to 6 carbon atoms; examples thereof include a diethylphosphoric acid amide group and a phenylphosphoric acid amide group);
a halogen atom (for example, a fluorine atom, a chlorine atom, a bromine atom, and an iodine atom);
a heterocyclic group (preferably a heterocyclic group having 1 to 30 carbon atoms and more preferably a heterocyclic group having 1 to 12 carbon atoms; examples thereof include a heterocyclic group having a heteroatom such as a nitrogen atom, an oxygen atom, and a sulfur atom, for example, an epoxy group, an oxetanyl group, an imidazolyl group, a pyridyl group, a quinolyl group, a furyl group, a piperidyl group, a morpholino group, a maleimide group, a benzoxazolyl group, a benzimidazolyl group, and a benzothiazolyl group);
a silyl group (preferably a silyl group having 3 to 40 carbon atoms, more preferably a silyl group having 3 to 30 carbon atoms, and still more preferably a silyl group having 3 to 24 carbon atoms; examples thereof include a trimethylsilyl group and a triphenylsilyl group);
a hydroxy group; a mercapto group; a cyano group; a nitro group; a hydroxamic acid group; a sulfino group; a hydrazino group; an imino group; an azo group; a carboxy group; a sulfonic acid group; and a phosphoric acid group.

### [Composition for Forming Light Absorption Anisotropic Film]

It is preferable that the light absorption anisotropic film according to the embodiment of the present invention is formed of a composition for forming a light absorption anisotropic film, which contains a liquid crystal compound and a dichroic substance.

In addition to the liquid crystal compound and the dichroic substance, the composition for forming a light absorption anisotropic film preferably contains a polymerization initiator, a solvent, and the like, and may further contain the above-described other components.

The liquid crystal compound and the dichroic substance, contained in the composition for forming a light absorption anisotropic film, are respectively the same as the liquid crystal compound and the dichroic substance contained in the light absorption anisotropic film according to the embodiment of the present invention.

It is preferable that contents of the liquid crystal compound and the dichroic substance with respect to the total solid content mass of the composition for forming a light absorption anisotropic film are respectively the same as the contents of the liquid crystal compound and the dichroic substance with respect to the total mass of the light absorption anisotropic film according to the embodiment of the present invention.

Here, the “total solid content in the composition for forming a light absorption anisotropic film” denotes components excluding a solvent, and specific examples of the solid content include the liquid crystal compound, the dichroic substance, and the above-described other components.

The other components which can be contained in the composition for forming a light absorption anisotropic film are the same as the other components which can be contained in the light absorption anisotropic film according to the embodiment of the present invention.

It is preferable that the content of the other components with respect to the total solid content mass of the composition for forming a light absorption anisotropic film is the same as the content of the other components with respect to the total mass of the light absorption anisotropic film according to the embodiment of the present invention.

### <Polymerization Initiator>

It is preferable that the composition for forming a light absorption anisotropic film contains a polymerization initiator. The polymerization initiator is not particularly limited, but a compound having photosensitivity, that is, a photopolymerization initiator is preferable.

As the photopolymerization initiator, various compounds can be used without any particular limitation. Examples of the photopolymerization initiator include a-carbonyl compounds (U.S. Pat. Nos. 2,367,661A and 2,367,670A), acyloin ether (U.S. Pat. No. 2,448,828A), a-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyloxime compounds ([0065] of JP2016-27384A), and acylphosphine oxide compounds (JP1988-40799B (JP-S63-40799B), JP1993-29234B (JP-H5-29234B), JP1998-95788A (JP-H10-95788A), and JP1998-29997A (JP-H10-29997A)).

Commercially available products can also be used as such a photopolymerization initiator, and examples thereof include IRGACURE 184, IRGACURE 907, IRGACURE 369, IRGACURE 651, IRGACURE 819, IRGACURE OXE-01, and IRGACURE OXE-02, manufactured by BASF.

The polymerization initiator may be used alone or in combination of two or more kinds thereof.

In a case where the composition for forming a light absorption anisotropic film contains a polymerization initiator, a content of the polymerization initiator is preferably in a range of 0.01 to 30 parts by mass and more preferably in a range of 0.1 to 15 parts by mass with respect to 100 parts by mass of the total amount of the dichroic substance and the liquid crystal compound in the composition for forming a light absorption anisotropic film. The durability of the light absorption anisotropic film is enhanced in a case where the content of the polymerization initiator is 0.01 parts by mass or more, and the alignment degree of the light absorption anisotropic film is improved in a case where the content thereof is 30 parts by mass or less.

### <Solvent>

From the viewpoint of workability and the like, it is preferable that the composition for forming a light absorption anisotropic film contains a solvent.

Examples of the solvent include organic solvents such as ketones (such as acetone, 2-butanone, methyl isobutyl ketone, cyclopentanetanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane (chloroform), dichloroethane, dichlorobenzene, and chlorotoluene), esters (such as methyl acetate, ethyl acetate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water. These solvents may be used alone or in combination of two or more kinds thereof.

Among these solvents, from the viewpoint that the effect of the present invention is more excellent, it is preferable to use an organic solvent and it is more preferable to use halogenated carbons or ketones.

In a case where the composition for forming a light absorption anisotropic film contains a solvent, a content of the solvent is preferably 80% to 99% by mass, more preferably 83% to 98% by mass, and still more preferably 85% to 97% by mass with respect to the total mass of the composition for forming a light absorption anisotropic film.

### [Manufacturing Method of Light Absorption Anisotropic Film]

A method for manufacturing the light absorption anisotropic film according to the embodiment of the present invention includes a coating film-forming step of forming a coating film by applying a composition containing a liquid crystal compound, a dichroic substance, and a solvent; a first heating step of heating the coating film at a temperature higher than a melting point of the dichroic substance; a cooling step of cooling the coating film subjected to the first heating step; and a second heating step of heating the coating film subjected to the cooling step at a temperature lower than a phase transition temperature of the liquid crystal compound from a crystal state to a liquid crystal state by 15° C. or higher.

With the manufacturing method of a light absorption anisotropic film according to the embodiment of the present invention, the above-described light absorption anisotropic film according to the embodiment of the present invention can be easily obtained.

Hereinafter, the respective steps will be described.

### <Coating Film-Forming Step>

The coating film-forming step is a step of applying a composition containing a liquid crystal compound, a dichroic substance, and a solvent to form a coating film.

The composition used in the coating film-forming step is the same as the above-described composition for forming a light absorption anisotropic film, and thus the description thereof will not be repeated.

Here, the solvent contained in the composition is the same as the solvent described in the above composition for forming a light absorption anisotropic film, and among these, a solvent capable of dissolving the liquid crystal compound and the dichroic substance contained in the composition is preferable. Here, the solvent capable of dissolving the liquid crystal compound and the dichroic substance means that the mass of the liquid crystal compound dissolved in 100 g of the solvent at 25° C. is 0.5 g or more and the mass of the dichroic substance dissolved in 100 g of the solvent is 0.1 g or more.

Examples of the method of applying the composition include known methods such as a roll coating method, a gravure printing method, a spin coating method, a wire bar coating method, an extrusion coating method, a direct gravure coating method, a reverse gravure coating method, a die-coating method, a spraying method, and an ink jet method.

In the present step, it is preferable that the coating film is applied onto an alignment film.

### (Alignment Film)

The alignment film can be provided by methods such as rubbing treatment of an organic compound (preferably a polymer) on a film surface, oblique vapor deposition of an inorganic compound, formation of a layer having microgrooves, or accumulation of an organic compound (for example, ω-tricosanoic acid, dioctadecylmethylammonium chloride, or methyl stearate) by the Langmuir-Blodgett method (LB film). Furthermore, an alignment film in which an alignment function is generated by application of an electric field, application of a magnetic field, or irradiation with light has also been known. Among these, in the present invention, an alignment film formed by performing a rubbing treatment is preferable from the viewpoint of easily controlling a pretilt angle of the alignment film, and a photo-alignment film formed by irradiation with light is also preferable from the viewpoint of the uniformity of alignment.

### (1) Rubbing-Treated Alignment Film

A polymer material used for the alignment film formed by performing a rubbing treatment is described in a plurality of documents, and a plurality of commercially available products can be used. In the present invention, polyvinyl alcohol or polyimide, or derivatives thereof are preferably used. The alignment film can refer to the description on page 43, line 24 to page 49, line 8 of WO2001/88574A1. A thickness of the alignment film is preferably 0.01 to 10 μm and more preferably 0.01 to 1 μm.

### (2) Photo-Alignment Film

A photo-alignment material used for the alignment film formed by irradiation with light is described in a plurality of documents. In the present invention, preferred examples thereof include azo compounds described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; aromatic ester compounds described in JP2002-229039A; maleimide and/or alkenyl-substituted nadimide compounds having a photo-alignment unit, described in JP2002-265541A and JP2002-317013A; photo-crosslinkable silane derivatives described in JP4205195B and JP4205198B; and photo-crosslinkable polyimides, polyamides, or esters described in JP2003-520878A, JP2004-529220A, and JP4162850B. Azo compounds, photo-crosslinkable polyimides, polyamides, or esters are more preferable.

The photo-alignment film formed of the above-described material is irradiated with linearly polarized light or non-polarized light to produce a photo-alignment film.

In the present specification, the “irradiation with linearly polarized light” and the “irradiation with non-polarized light” are operations for causing a photo-reaction in the photo-alignment material. A wavelength of the light to be used varies depending on the photo-alignment material to be used, and is not particularly limited as long as the wavelength is required for the photo-reaction. A peak wavelength of the light to be used for irradiation with light is preferably 200 nm to 700 nm, and ultraviolet light having a peak wavelength of 400 nm or less is more preferable.

Examples of a light source used for the light irradiation include commonly used light sources, for example, lamps such as a tungsten lamp, a halogen lamp, a xenon lamp, a xenon flash lamp, a mercury lamp, a mercury xenon lamp, or a carbon arc lamp, various lasers [such as a semiconductor laser, a helium neon laser, an argon ion laser, a helium cadmium laser, and a yttrium aluminum garnet (YAG) laser], a light emitting diode, and a cathode ray tube.

As a method of obtaining the linearly polarized light, a method of using a polarizing plate (for example, iodine polarizing plate, dichroic substance polarizing plate, and wire grid polarizing plate), a method of using a prismatic element (for example, Glan-Thomson prism) or a reflective type polarizer using Brewster's angle, or a method of using light emitted from a polarized laser light source can be adopted. In addition, by using a filter, a wavelength conversion element, or the like, only light having a required wavelength may be radiated selectively.

In a case where light to be applied is the linearly polarized light, a method of applying light vertically or obliquely to the upper surface of the alignment film or the surface of the alignment film from the rear surface is employed. An incidence angle of light varies depending on the photo-alignment material, but is preferably 0° to 90° (vertical) and more preferably 40° to 90°

In a case where the light to be applied is the non-polarized light, the alignment film is irradiated with the non-polarized light obliquely. An incidence angle is preferably 10° to 80°, more preferably 20° to 60°, and particularly preferably 30° to 50°.

The irradiation time is preferably 1 minute to 60 minutes and more preferably 1 minute to 10 minutes.

In a case where patterning is required, a method of performing irradiation with light using a photomask as many times as necessary for pattern preparation or a method of writing a pattern by laser light scanning can be employed.

The coating film-forming step may include a drying treatment. As a result, components such as the solvent can be removed from the coating film.

The drying treatment may be performed by a method of allowing the coating film to stand at room temperature for a predetermined time (for example, natural drying) or a method of at least one of heating or blowing.

A temperature of the drying treatment is preferably a temperature lower than the melting point of the dichroic substance, and is, for example, 25° C. to 110° C. In addition, a drying time is, for example, 200 seconds or less.

The dichroic substance contained in the composition may be aligned by the above-described coating film-forming step. For example, in a case where the coating film is dried and the solvent is removed from the coating film, the dichroic substance contained in the coating film may be aligned.

### <First Heating Step>

The first heating step is a step of heating the above-described coating film at a temperature higher than the melting point of the dichroic substance. As a result, the dichroic substance contained in the coating film is aligned, and the alignment degree of the obtained light absorption anisotropic film is further increased.

In the present invention, the melting point of the dichroic substance (hereinafter, also simply referred to as “T₁”; the unit is ° C.) means a melting peak temperature in a differential scanning calorimetry (DSC) curve obtained by heating the dichroic substance using DSC. Measurement conditions by DSC are a measurement temperature range of −50° C. to 170° C. and a temperature rising rate of 10° C./min.

In a case where the coating film contains a plurality of kinds of dichroic substances, the T₁ means a melting point of a dichroic substance having the highest melting point among all the dichroic substances contained in the coating film (composition).

The heating temperature of the coating film in the first heating step (hereinafter, also referred to as “first heating temperature”) is a temperature higher than T₁, and from the viewpoint that the alignment degree of the light absorption anisotropic film is more excellent, the heating temperature is preferably (T₁+5° C.) or higher, more preferably (T₁+8° C.) or higher, and still more preferably (T₁+10)° C. or higher.

From the viewpoint of reducing damage to the coating film, the first heating temperature is preferably (T₁+80° C.) or lower and more preferably (T₁+50° C.) or lower.

A heating time is preferably 1 to 300 seconds and more preferably 20 to 130 seconds.

### <Cooling Step>

The cooling step is a step of cooling the above-described coating film subjected to the above-described first heating step.

In the cooling and fixing, it is preferable to cool the coating film to approximately room temperature (20° C. to 25° C.). As a result, the alignment of the dichroic substance contained in the coating film is further fixed, and the alignment degree of the light absorption anisotropic film is further increased. A cooling unit is not particularly limited, and the cooling treatment can be performed according to a known method.

### <Second Heating Step>

The second heating step is a step of heating the above-described coating film subjected to the above-described cooling step at a temperature lower than a phase transition temperature of the liquid crystal compound from a crystal state to a liquid crystal state by 15° C. or higher.

At the heating temperature of the coating film in the present step, the liquid crystal compound maintains a crystal state, and thus the movement of the dichroic substance molecules present in the film, which do not form the associate, is restricted. Accordingly, it is presumed that the size of the associate of the dichroic substance is suppressed from being excessively large, and thus the light absorption anisotropic film according to the embodiment of the present invention, satisfying the above expression (1), is obtained.

In the present invention, the phase transition temperature of the liquid crystal compound from the crystal state to the liquid crystal state (hereinafter, also simply referred to as “T₂”; the unit is ° C.) means a glass transition point in a differential scanning calorimetry (DSC) curve obtained by heating the liquid crystal compound using DSC. Measurement conditions by DSC are a measurement temperature range of −50° C. to 170° C. and a temperature rising rate of 10° C./min.

In a case where the coating film contains a plurality of kinds of liquid crystal compounds, the T₂ means a phase transition temperature at which a liquid crystal compound having the highest content among all types of liquid crystal compounds contained in the coating film (composition) transitions from a crystal state to a liquid crystal state.

A heating temperature of the coating film in the second heating step (hereinafter, also referred to as “second heating temperature”) is (T₂−15° C.) or lower, preferably (T₂−25° C.) or lower.

From the viewpoint of heat resistance, the second heating temperature is preferably (T₂−60° C.) or higher and more preferably (T₂−45° C.) or higher.

A heating time is preferably 1 to 80 seconds and more preferably 30 to 70 seconds.

### <Other Steps>

The present manufacturing method may include a step of curing the light absorption anisotropic film after the above-described second heating step (hereinafter, also referred to as “curing step”).

The curing step is performed by, for example, at least one of heating or light irradiation (exposure). Among these, it is preferable that the curing step is performed by irradiating the optically functional film with light.

Various light sources such as infrared rays, visible light, and ultraviolet rays can be used as a light source for curing, but ultraviolet rays are preferable. In addition, ultraviolet rays may be applied while the film is heated during curing, or ultraviolet rays may be applied through a filter which transmits only a specific wavelength.

In addition, the exposure may be performed under a nitrogen atmosphere. In a case where the curing of the light absorption anisotropic film proceeds by radical polymerization, since inhibition of polymerization by oxygen is reduced, it is preferable that the exposure is performed in a nitrogen atmosphere.

The present manufacturing method may include a step of heating the coating film after the above-described first heating step and before the above-described cooling step. A heating temperature of the present step (hereinafter, also referred to as “third heating temperature”) is a temperature at which the above-described first heating temperature and the above-described second heating temperature are not satisfied. For example, in a case where the first heating temperature>the second heating temperature, it is preferable to satisfy a relationship of the first heating temperature>the third heating temperature>the second heating temperature.

The present manufacturing method may include a step of cooling the coating film (light absorption anisotropic film) after the above-described second heating step. Since the present step is the same as the above-described cooling step, the description thereof will not be repeated.

### [Laminate]

The laminate according to the embodiment of the present invention includes a base material and the above-described light absorption anisotropic film disposed on the base material, and may include an alignment film between the base material and the light absorption anisotropic film.

Hereinafter, each member constituting the laminate according to the embodiment of the present invention will be described.

### [Base Material]

As the base material, a transparent support is preferable. The transparent support is intended to be a support in which the transmittance of visible light is 60% or more, and the transmittance is preferably 80% or more and more preferably 90% or more.

As the transparent support, a known transparent resin film such as a transparent resin plate, a transparent resin sheet, or the like can be used without particular limitation.

As the transparent resin film, a cellulose acylate film (such as a cellulose triacetate film (refractive index: 1.48), a cellulose diacetate film, a cellulose acetate butyrate film, and a cellulose acetate propionate film), a polyethylene terephthalate film, a polyether sulfone film, a polyacrylic resin film, a polyurethane-based resin film, a polyester film, a polycarbonate film, a polysulfone film, a polyether film, a polymethylpentene film, a polyetherketone film, a (meth)acrylonitrile film, or the like can be used.

Among these, a cellulose acylate film which is highly transparent, has a small optical birefringence, is easily produced, and is typically used as a protective film of a polarizing plate is preferable, and a cellulose triacetate film is more preferable.

A thickness of the base material is usually 20 to 100 μm.

In the present invention, it is particularly preferable that the base material is a cellulose ester-based film having a film thickness 20 to 70 μm.

### [Light Absorption Anisotropic Film]

The light absorption anisotropic film according to the embodiment of the present invention is as described above, and thus the description thereof will not be repeated.

A thickness of the light absorption anisotropic film is not particularly limited, but is preferably 100 to 8,000 nm and more preferably 300 to 5,000 nm.

### [Alignment Film]

The alignment film (alignment layer) is as described above, and thus the description thereof will not be repeated.

### [λ/4 Plate]

One of suitable aspects of the laminate according to the embodiment of the present invention is an aspect having a light absorption anisotropic film and a λ/4 plate. Such a laminate is suitably used as a circularly polarizing plate.

The λ/4 plate is a plate having a λ/4 function, specifically, a plate having a function of converting linearly polarized light having a specific wavelength into circularly polarized light (or converting circularly polarized light into linearly polarized light).

Specific examples of an aspect in which the λ/4 plate has a monolayer structure include a stretched polymer film and a retardation film in which a light absorption anisotropic film having a λ/4 function is provided on a support. In addition, specific examples of an aspect in which the λ/4 plate has a multilayer structure include a broadband λ/4 plate obtained by laminating a N/4 plate and a λ/2 plate.

The λ/4 plate and the light absorption anisotropic film may be provided to be in contact with each other, or another layer may be provided between the λ/4 plate and the light absorption anisotropic film. Examples of such a layer include a pressure-sensitive adhesive layer or an adhesive layer for ensuring adhesiveness, and a barrier layer.

In addition, it is preferable that the λ/4 plate is a positive A-plate (positive A plate) and has wavelength dispersibility of a phase difference Re which is reverse-dispersive wavelength dispersibility. Here, the reverse-dispersive wavelength dispersibility refers to that Re(λ) and Rth(λ) have larger values as the wavelength λ increases, and in this case, the phase difference Re(λ) satisfies the following expressions (1-1) and (1-2).

$$Re ( 450 ) / Re ( 550 ) > 1. \qquad Expression ( 1 - 1 )$$

$$Re ( 650 ) / Re ( 550 ) > 1. \qquad Expression ( 1 - 2 )$$

Here, Re(λ) and Rth(λ) represent an in-plane phase difference and a thickness direction phase difference at a wavelength λ, respectively. As Re(λ) and Rth(λ), values measured at the wavelength λ with AxoScan OPMF-1 (manufactured by Opto Science, Inc.) is used. By inputting an average refractive index ((nx+ny+nz)/3) and a film thickness (d(μm)) in AxoScan, a slow axis direction (°), Re(λ)=(nx−ny)×d, and Rth(λ)=((nx+ny)/2−nz)×d are calculated.

In addition, nx and ny are refractive indices in the in-plane direction of an optical member, and typically, nx represents a refractive index of a slow axis azimuth and ny represents a refractive index of a fast axis azimuth (that is, the azimuth orthogonal to the slow axis). In addition, nz is a refractive index in the thickness direction. nx, ny, and nz can be measured, for example, with an Abbe refractometer (NAR-4T, manufactured by Atago Co., Ltd.) using a sodium lamp (λ=589 nm) as a light source. In addition, in a case of measuring wavelength dependence, it can be measured with a multi-wavelength Abbe refractometer DR-M2 (manufactured by Atago Co., Ltd.) in combination with a dichroic filter. In addition, values from Polymer Handbook (John Wiley & Sons, Inc.) and catalogs of various optical films can also be used.

The positive A-plate refers to an optical member in which the refractive indices nx, ny, and nz satisfy the following expression (1-3). However, in the expression (1-3), “≈” includes not only a case in which both are completely the same but also a case in which both are substantially the same.

$$n x > ny \approx nz \qquad Expression ( 1 - 3 )$$

Examples of a material used in a case of producing the λ/4 plate include an interface improver. A preferred aspect of the interface improver is the same as the interface improver which may be contained in the above-described light absorption anisotropic film.

### [Barrier Layer]

It is preferable that the laminate according to the embodiment of the present invention includes a barrier layer together with the base material and the light absorption anisotropic film.

Here, the barrier layer is also referred to as a gas-shielding layer (oxygen-shielding layer), and has a function of protecting the polarizer of the present invention from gas such as oxygen in the atmosphere, the moisture, or the compound contained in an adjacent layer.

The barrier layer can refer to, for example, the description in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A, and paragraphs [0021] to [0031] of JP2005-169994A.

### [Image Display Device]

The image display device according to the embodiment of the present invention preferably includes the above-described light absorption anisotropic film according to the embodiment of the present invention or the above-described laminate according to the embodiment of the present invention, and further includes a display element.

The display element is preferably disposed on a polarizer side of the laminate (that is, a side opposite to the base material). The polarizer and the liquid crystal cell may be laminated through a known adhesive layer or a known pressure-sensitive adhesive layer.

The display element used in the display device according to the embodiment of the present invention is not particularly limited, and examples thereof include a liquid crystal cell, an organic electroluminescence (hereinafter, abbreviated as “EL”) display panel, and a plasma display panel.

Among these, a liquid crystal cell or an organic EL display panel is preferable. That is, as the display device according to the embodiment of the present invention, a liquid crystal display device obtained by using a liquid crystal cell as a display element or an organic EL display device obtained by using an organic EL display panel as a display element is preferable.

Some image display devices are thin and can be formed into a curved surface. Since the light absorption anisotropic film used in the present invention is thin and easily bent, the light absorption anisotropic film can be suitably applied to an image display device having a curved display surface.

In addition, some image display devices have a pixel density of more than 250 ppi and are capable of high-definition display. The light absorption anisotropic film used in the present invention can be suitably applied to such a high-definition image display device without causing moire.

### [Liquid Crystal Display Device]

Preferred examples of the liquid crystal display device which is an example of the display device according to the embodiment of the present invention include an aspect in which the liquid crystal display device includes the above-described light absorption anisotropic film according to the embodiment of the present invention and a liquid crystal cell. A liquid crystal display device including the above-described laminate according to the embodiment of the present invention (here, the laminate does not include the 24 plate) and a liquid crystal cell is more suitable.

In the present invention, between the polarizers provided on both sides of the liquid crystal cell, it is preferable that the laminate according to the embodiment of the present invention is used as a front-side polarizer and more preferable that the laminate according to the embodiment of the present invention is used as a front-side polarizer and a rear-side polarizer.

Hereinafter, the liquid crystal cell constituting the liquid crystal display device will be described in detail.

### <Liquid Crystal Cell>

It is preferable that the liquid crystal cell used for the liquid crystal display device is in a vertical alignment (VA) mode, an optically compensated bend (OCB) mode, an in-plane-switching (IPS) mode, or a twisted nematic (TN) mode, but the present invention is not limited thereto.

In the liquid crystal cell in a TN mode, rod-like liquid crystalline molecules are substantially horizontally aligned at the time of no voltage application and further twisted aligned at 60° to 120°. The liquid crystal cell in a TN mode is most frequently used as a color TFT liquid crystal display device and is described in a plurality of documents.

In the liquid crystal cell in a VA mode, rod-like liquid crystalline molecules are substantially vertically aligned at the time of no voltage application. Examples of the VA mode liquid crystal cells include (1) a VA mode liquid crystal cell in a narrow sense (described in JP1990-176625A (JP-H02-176625A)) in which rod-like liquid crystal molecules are substantially aligned vertically in a case where no voltage is applied thereto and are substantially aligned horizontally in a case where a voltage is applied thereto, (2) a multi-domain VA mode (MVA mode) liquid crystal cell for enlarging the viewing angle (SID97, described in Digest of Tech. Papers (Proceedings) 28 (1997) 845), (3) a liquid crystal cell in a mode (n-ASM mode) in which rod-like liquid crystal molecules are substantially aligned vertically in a case where no voltage is applied thereto and are aligned in twisted multi-domain alignment in a case where a voltage is applied thereto (described in Proceedings of Japanese Liquid Crystal Conference, 58 and 59 (1998)), and (4) a SURVIVAL mode liquid crystal cell (presented in LCD International 98). The liquid crystal cell may be any one of a patterned vertical alignment (PVA) type, an optical alignment type, and a polymer-sustained alignment (PSA) type. These modes are described in detail in JP2006-215326A and JP2008-538819A.

In the liquid crystal cell in an IPS mode, liquid crystal compounds are aligned substantially parallel to the substrate, and the liquid crystalline molecules respond planarly through application of an electric field parallel to the substrate surface. That is, the liquid crystal compounds are aligned in the plane in a state where no electric field is applied. In the IPS mode, black display is carried out in a state where no electric field is applied, and absorption axes of a pair of upper and lower polarizing plates are orthogonal to each other. A method of reducing light leakage during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

### [Organic EL Display Device]

As an organic EL display device which is an example of the display device according to the embodiment of the present invention, an embodiment of a display device including the above-described laminate (preferably including the λ/4 plate) according to the embodiment of the present invention and an organic EL display panel in this order from the viewing side is suitably exemplified. In this case, it is preferable that the laminate is formed such that the protective layer, the light absorption anisotropic film, the alignment film, and the λ/4 plate are disposed in this order from the viewing side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to Examples. Materials, used amounts, ratios, treatment contents, treatment procedures, and the like described in Examples can be appropriately changed without departing from the spirit of the present invention. Therefore, the scope of the present invention should not be construed as being limited to Examples.

### Example 1

### [Production of Transparent Support]

The following composition was put into a mixing tank and stirred, thereby preparing a cellulose acetate solution used as a core layer cellulose acylate dope.

Core layer cellulose acylate dope

| | | |
|---|---|---|
| Cellulose acetate having acetyl substitution | 100 | parts by mass |
| degree of 2.88 | | |
| Polyester compound B described in Examples of | 12 | parts by mass |
| JP2015-227955A | | |
| Compound F shown below | 2 | parts by mass |
| Methylene chloride (first solvent) | 430 | parts by mass |
| Methanol (second solvent) | 64 | parts by mass |

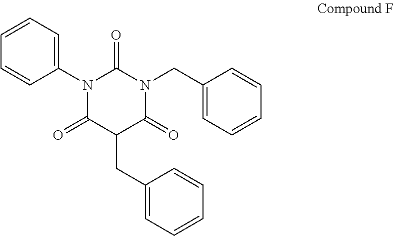 [SMILES: O=C1C(Cc2ccccc2)C(=O)N(c2ccccc2)C(=O)N1Cc1ccccc1]

10 parts by mass of the following matte agent solution was added to 90 parts by mass of the core layer cellulose acylate dope to prepare a cellulose acetate solution to be used as an outer layer cellulose acylate dope.

Matting agent solution

| | | |
|---|---|---|
| Silica particles having an average particle diameter | 2 | parts by mass |
| of 20 nm (AEROSIL R972, manufactured by | | |
| Nippon Aerosil Co., Ltd.) | | |
| Methylene chloride (first solvent) | 76 | parts by mass |
| Methanol (second solvent) | 11 | parts by mass |
| Core layer cellulose acylate dope described above | 1 | part by mass |

The core layer cellulose acylate dope and the outer layer cellulose acylate dope were filtered through filter paper having an average hole diameter of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film on the drum was peeled off in a state in which the solvent content in the film was approximately 20% by mass, both ends of the film in the width direction were fixed by tenter clips, and the film was dried while being stretched at a stretching ratio of 1.1 times in the lateral direction.

Thereafter, the obtained film was further dried by being transported between the rolls of the heat treatment device to produce a transparent support having a thickness of 40 μm, and the transparent support was used as a cellulose acylate film A1.

### [Production of Photo-Alignment Film B1]

The above-described cellulose acylate film A1 was continuously coated with a composition for forming a photo-alignment film described below with a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film, thereby obtaining a triacetyl cellulose (TAC) film with the photo-alignment film. A film thickness of the photo-alignment film was 0.25 μm.

Composition for forming alignment film

| | | |
|---|---|---|
| Polymer PA-1 shown below | 100.00 | parts by mass |
| Acid generator PAG-1 shown below | 8.25 | parts by mass |
| Stabilizer DIPEA shown below | 0.6 | parts by mass |
| Xylene | 1126.60 | parts by mass |
| Methyl isobutyl ketone | 125.18 | parts by mass |

Polymer PA-1 (in the formulae, the numerical value described in each repeating unit denotes the content (% by mass) of each repetition unit with respect to all repeating units)

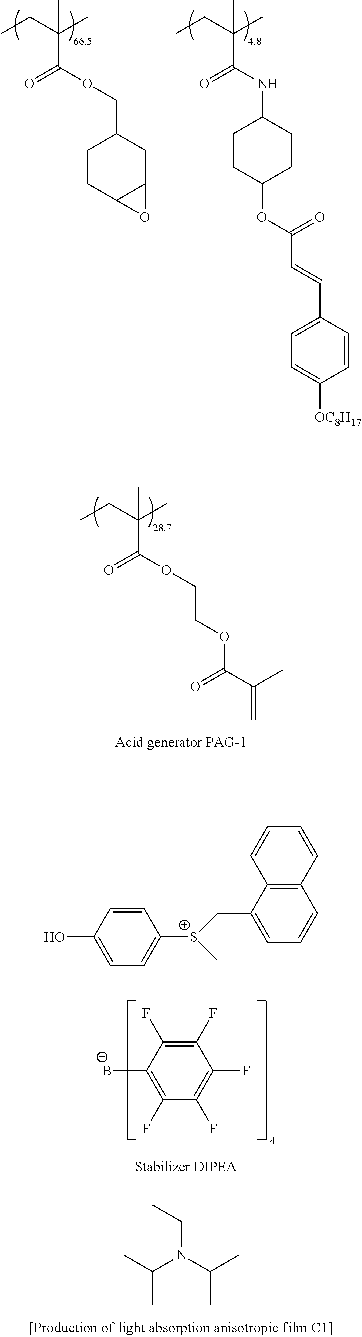

The composition 1 for forming a light absorption anisotropic film, having the following formulation, was continuously applied onto the obtained photo-alignment film B1 using a wire bar to form a coating film (coating film-forming step).

Next, the coating film was heated at 140° C. for 15 seconds (first heating step) and heated at 80° C. for 5 seconds, and the coating film was cooled to room temperature (23° C.) (cooling step). Next, the coating film was heated at 55° C. for 60 seconds (second heating step) and cooled to room temperature again.

Here, a melting point of a dichroic substance Dye-C1 was 120° C., a melting point of a dichroic substance Dye-C2 was 120° C., a melting point of a dichroic substance Dye-M1 was 120° C., and a melting point of a dichroic substance Dye-Y1 was 110° C.; and the melting points of all the dichroic substances contained in the composition 1 for forming a light absorption anisotropic film were lower than the heating temperature (140° C.) of the first heating step.

In addition, a phase transition temperature (temperature at the time of transition from a crystal state to a liquid crystal state) of the liquid crystal compound L-1 having the highest content among the liquid crystal compounds contained in the composition was 85° C., which was 30° C. higher than the heating temperature (55° C.) in the second heating step.

The melting point (T₁° C. described above) of the dichroic substance and the phase transition temperature (T₂° C. described above) of the liquid crystal compound were measured by the above-described methods. The same applies to other examples described later.

Thereafter, the coating film was irradiated with light for 2 seconds under an irradiation condition of illuminance of 200 mW/cm² using a light emitting diode (LED) lamp (central wavelength: 365 nm), thereby producing a light absorption anisotropic film C1 (polarizer) (thickness: 1.8 μm) on the photo-alignment film B1.

In a case where a transmittance of the light absorption anisotropic film C1 in a wavelength range of 280 to 780 nm was measured with a spectrophotometer, and the average transmittance of visible light was 42%.

The absorption axis of the light absorption anisotropic film C1 was in the plane of the light absorption anisotropic film C1, and was orthogonal to a width direction of the cellulose acylate film A1.

Formulation of composition 1 for forming
light absorption anisotropic film

| | |
|---|---|
| Dichroic substance Dye-C1 shown below | 0.15 parts by mass |
| Dichroic substance Dye-C2 shown below | 0.44 parts by mass |
| Dichroic substance Dye-M1 shown below | 0.14 parts by mass |
| Dichroic substance Dye-Y1 shown below | 0.25 parts by mass |
| Liquid crystal compound L-1 shown below | 1.97 parts by mass |
| Liquid crystal compound L-2 shown below | 0.84 parts by mass |
| Adhesion improver A-1 shown below | 0.06 parts by mass |
| Polymerization initiator IRGACURE | 0.12 parts by mass |
| OXE-02 (manufactured by BASF) | |
| Surfactant F-1 shown below | 0.01 parts by mass |
| Cyclopentanone | 93.61 parts by mass |
| Benzyl alcohol | 2.40 parts by mass |

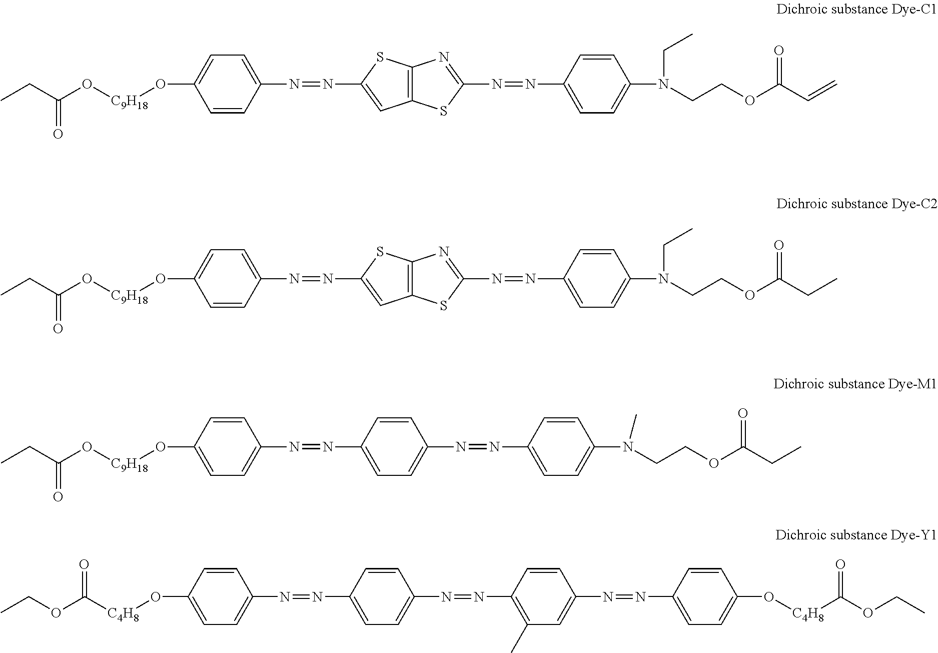

Liquid crystal compound L-1 (in the formulae, the numerical value (“59”, “15”, or “26”) described in each repeating unit denotes the content (% by mass) of each repetition unit with respect to all repeating units)

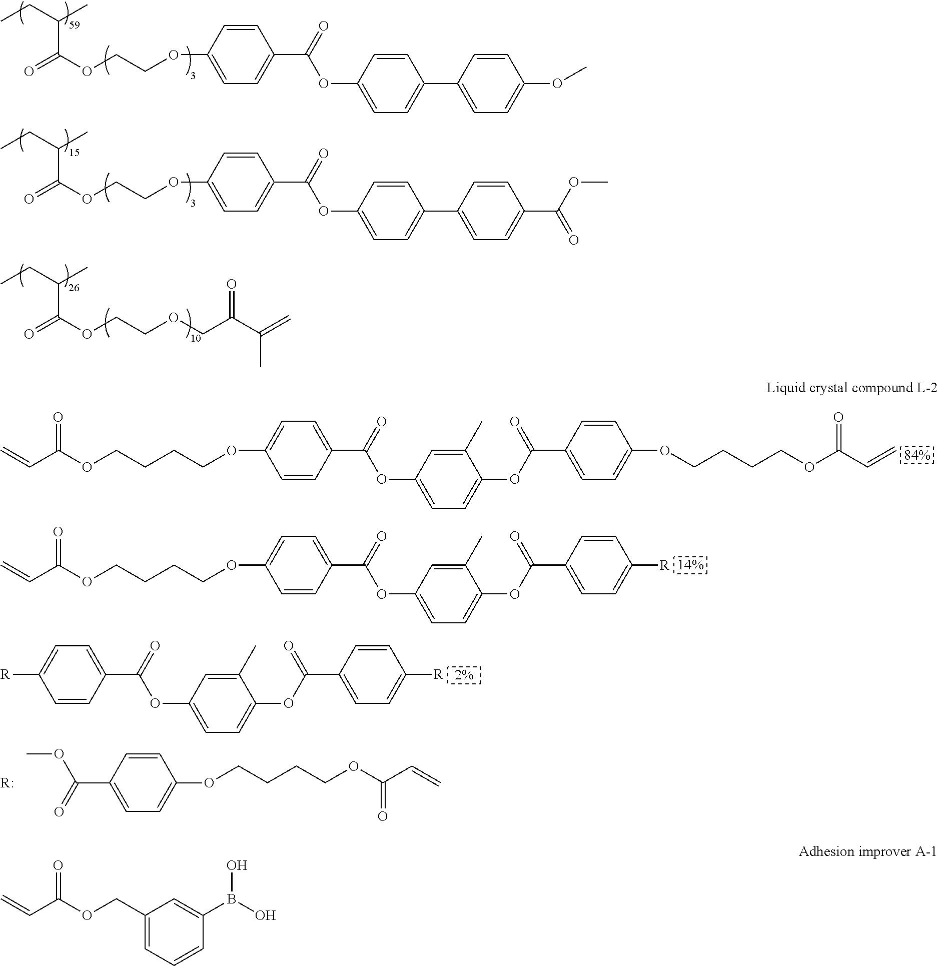

Surfactant F-1 (in the formulae, the numerical value described in each repeating unit denotes the content (% by mass) of each repetition unit with respect to all repeating units)

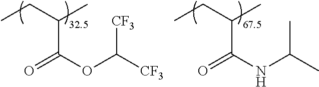

### [Formation of Oxygen-Shielding Layer D1]

The light absorption anisotropic film C1 was continuously coated with a coating liquid D1 having the following formulation with a wire bar. Thereafter, the film was dried with hot air at 80° C. for 5 minutes, thereby obtaining a laminate on which an oxygen-shielding layer D1 consisting of polyvinyl alcohol (PVA) and having a thickness of 1.0 μm was formed, that is, obtaining a laminate CP1 in which the cellulose acylate film A1 (transparent support), the photo-alignment film B1, the light absorption anisotropic film C1, and the oxygen-shielding layer D1 were provided adjacent to each other in this order.

Formulation of coating liquid D1 for
forming oxygen-shielding layer

| | |
|---|---|
| Modified polyvinyl | 3.80 parts by mass |
| alcohol shown below | |
| Initiator Irg2959 | 0.20 parts by mass |
| Water | 70 parts by mass |
| Methanol | 30 parts by mass |

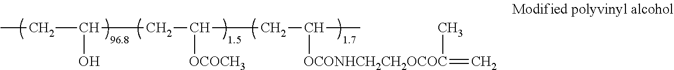

### [Production of TAC Film Including Positive a Plate]

The above-described cellulose acylate film A1 was continuously coated with a coating liquid E1 for forming a photo-alignment film, having the following formulation, with a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film E1 having a thickness of 0.2 μm, thereby obtaining a TAC film with the photo-alignment film.

Coating liquid E1 for forming photo-alignment film

| | |
|---|---|
| Polymer PA-2 shown below | 100.00 parts by mass |
| Acid generator PAG-1 | 5.00 parts by mass |
| shown above | |
| Acid generator CPI-110TF | 0.005 parts by mass |
| shown below | |
| Isopropyl alcohol | 16.50 parts by mass |
| Butyl acetate | 1072.00 parts by mass |
| Methyl ethyl ketone | 268.00 parts by mass |

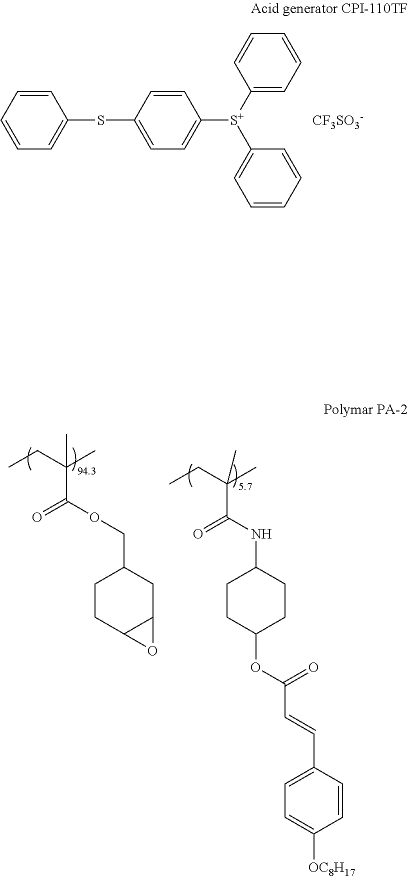

The above-described photo-alignment film E1 was coated with a composition F1 having the following formulation using a bar coater. The coating film formed on the photo-alignment film E1 was heated to 120° C. with hot air, cooled to 60° C., irradiated with ultraviolet rays having a wavelength of 365 nm with an illuminance of 100 mJ/cm² using a high-pressure mercury lamp in a nitrogen atmosphere, and continuously irradiated with ultraviolet rays with an illuminance of 500 mJ/cm² while being heated at 120° C., so that the alignment of the liquid crystal compound was immobilized, thereby producing a TAC film having a positive A plate F1.

A thickness of the positive A plate F1 was 2.5 μm, and an Re (550) was 144 nm. In addition, the positive A plate satisfied a relationship of “Re(450)≤Re(550)≤Re(650)”. Re(450)/Re(550) was 0.82.

Composition F1

| | |
|---|---|
| Polymerizable liquid crystal compound | 43.50 parts by mass |
| LA-1 shown below | |
| Polymerizable liquid crystal compound | 43.50 parts by mass |
| LA-2 shown below | |
| Polymerizable liquid crystal compound | 8.00 parts by mass |
| LA-3 shown below | |
| Polymerizable liquid crystal compound | 5.00 parts by mass |
| LA-4 shown below | |
| Polymerization initiator PI-1 shown below | 0.55 parts by mass |
| Leveling agent T-1 shown below | 0.20 parts by mass |
| Cyclopentanone | 235.00 parts by mass |

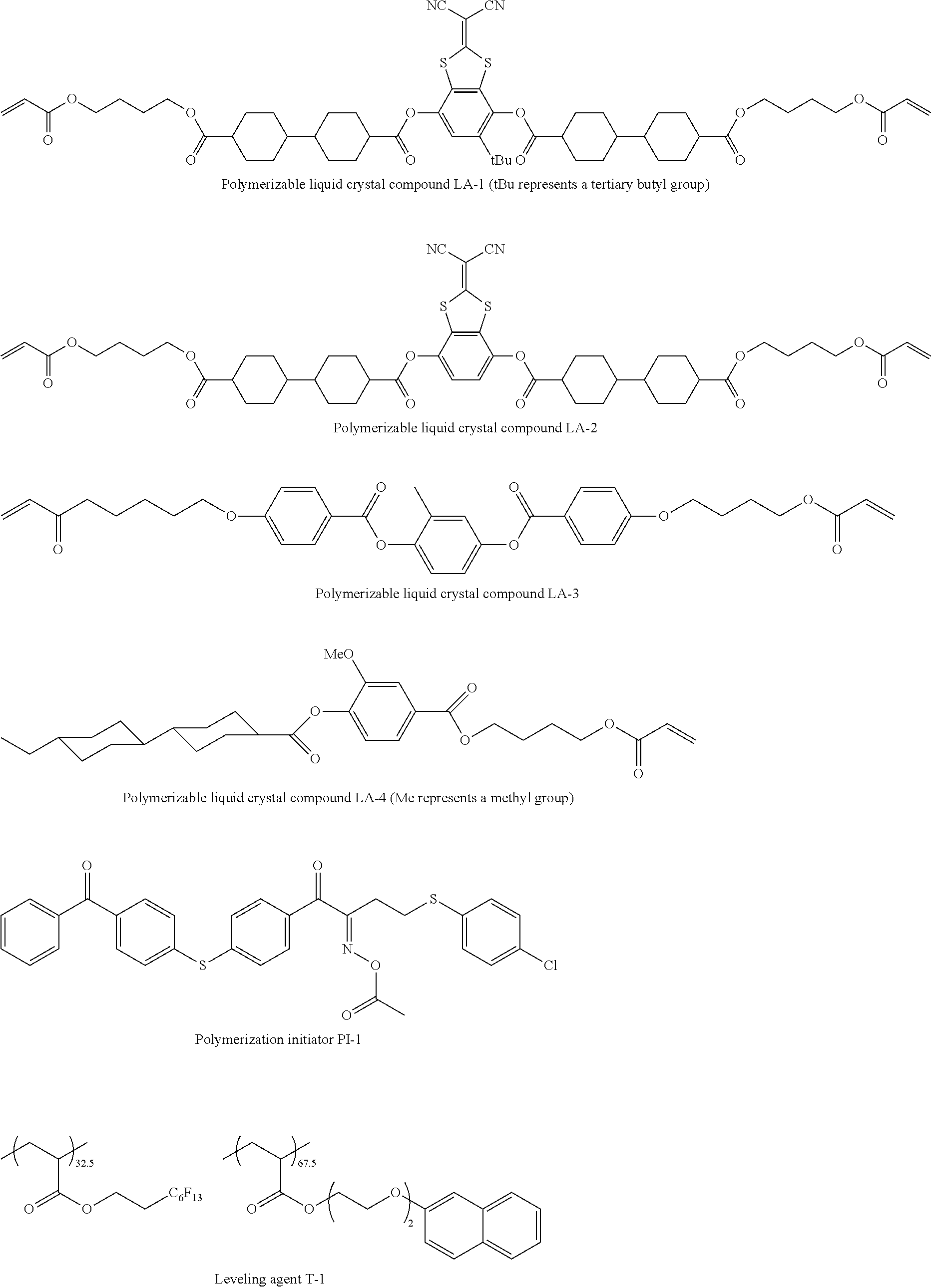

### [Production of TAC Film Including Positive C Plate H1]

The above-described cellulose acylate film A1 was used as a temporary support.

After passing the cellulose acylate film A1 through a dielectric heating roll at a temperature of 60° C. to raise the film surface temperature to 40° C., an alkaline solution having the formulation shown below was applied onto one surface of the film using a bar coater at a coating amount of 14 ml/m², followed by heating to 110° C., and transportation of the film under a steam type far-infrared heater manufactured by Noritake Company Limited for 10 seconds.

Next, the film was coated with pure water such that the coating amount reached 3 ml/m² using the same bar coater. Next, the film was washed with water by a fountain coater and drained by an air knife three times, and then transported to a drying zone at 70° C. for 10 seconds and dried to produce a cellulose acylate film A1 subjected to an alkali saponification treatment.

(Alkaline solution)

| | | |
|---|---|---|
| Potassium hydroxide | 4.7 | parts by mass |
| Water | 15.8 | parts by mass |
| Isopropanol | 63.7 | parts by mass |
| Fluorine-containing surfactant SF-1 | 1.0 | part by mass |
| (C₁₄H₂₉O(CH₂CH₂O)₂₀H) | | |
| Propylene glycol | 14.8 | parts by mass |

The cellulose acylate film A1 which had been subjected to the alkali saponification treatment was continuously coated with a coating liquid G1 for forming a photo-alignment film, having the following formulation, using a #8 wire bar. The obtained film was dried with hot air at 60° C. for 60 seconds, and further dried with hot air at 100° C. for 120 seconds to form a photo-alignment film G1.

Coating liquid G1 for forming photo-alignment film

| | |
|---|---|
| Polyvinyl alcohol (PVA103 manufactured | 2.4 parts by mass |
| by Kuraray Co., Ltd.) | |
| Isopropyl alcohol | 1.6 parts by mass |
| Methanol | 36 parts by mass |
| Water | 60 parts by mass |

The photo-alignment film G1 was coated with a coating liquid H1 for forming a positive C plate, having the following formulation, the obtained coating film was aged at 60° C. for 60 seconds and irradiated with ultraviolet rays at an illuminance of 1000 mJ/cm² in the air using an air-cooled metal halide lamp at an illuminance of 70 mW/cm² (manufactured by Eye Graphics Co., Ltd.), and the alignment state thereof was fixed to vertically align the liquid crystal compound, thereby producing a TAC film having a positive C plate H1 with a thickness of 0.5 μm.

Rth (550) of the obtained positive C plate was −60 nm.

Coating liquid H1 for forming positive C plate

| | | |
|---|---|---|
| liquid crystal compound LC-1 shown below | 80 | parts by mass |
| liquid crystal compound LC-2 shown below | 20 | parts by mass |
| Vertically aligned liquid crystal compound | 1 | part by mass |
| alignment agent S01 shown below | | |
| Ethylene oxide-modified trimethylolpropane | 8 | parts by mass |
| triacrylate (V # 360, manufactued by Osaka | | |
| Organic Chemical Industry Ltd.) | | |
| IRGACURE 907 (manufactured by BASF SE) | 3 | parts by mass |
| KAYACURE DETX (manufactured by Nippon | 1 | part by mass |
| Kayaku Co., Ltd.) | | |
| Compound B03 shown below | 0.4 | parts by mass |
| Methyl ethyl ketone | 170 | parts by mass |
| Cyclohexanone | 30 | parts by mass |

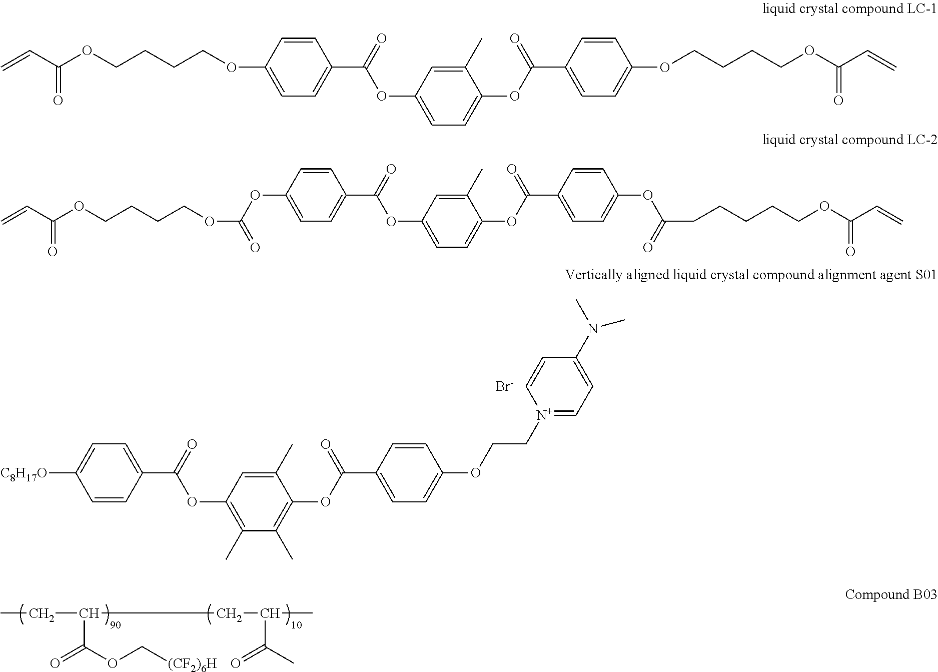

### [Production of Pressure Sensitive Adhesive (Pressure-Sensitive Adhesive Layer)]

An acrylate-based polymer was prepared according to the following procedure.

Butyl acrylate (95 parts by mass) and acrylic acid (5 parts by mass) were polymerized by a solution polymerization method in a reaction container equipped with a cooling pipe, a nitrogen introduction pipe, a thermometer, and a stirrer, thereby obtaining an acrylate-based polymer (NA1) with an average molecular weight of 2,000,000 and a molecular weight distribution (Mw/Mn) of 3.0.

Next, an acrylate-based pressure sensitive adhesive was produced with the following formulation using the obtained acrylate-based polymer (NA1). Each separate film which had been subjected to a surface treatment with a silicone-based release agent was coated with the composition using a die coater, dried in an environment of 90° C. for 1 minute, and irradiated with ultraviolet rays (UV) under the following conditions, thereby obtaining the following acrylate-based pressure sensitive adhesive N1 (pressure-sensitive adhesive layer N1). The formulation and the film thickness of the acrylate-based pressure sensitive adhesive are shown below.

### <UV Irradiation Conditions>

Electrodeless lamp H bulb (Fusion Co., Ltd.)
Illuminance: 600 mW/cm², light intensity: 150 mJ/cm²
The UV illuminance and the light intensity were measured using “UVPF-36” (manufactured by Eye Graphics Co., Ltd.).

Acrylate-based pressure sensitive
adhesive N1 (film thickness: 15 μm)

| | |
|---|---|
| Acrylate-based polymer (NA1) | 100 parts by mass |
| (A) Polyfunctional acrylate-based | 11.1 parts by mass |
| monomer shown below | |
| (B) Photopolymerization initiator | 1.1 parts by mass |
| shown below | |
| (C) Isocyanate-based crosslinking | 1.0 part by mass |
| agent shown below | |
| (D) Silane coupling agent | 0.2 parts by mass |
| shown below | |

(A) Polyfunctional acrylate-based monomer: tris(acryloyloxyethyl) isocyanurate, molecular weight = 423, trifunctional type (manufactured by Toagosei Co., Ltd., trade name “ARONIX M-315”)
(B) Photopolymerization initiator: mixture of benzophenone and 1-hydroxycyclohexyl phenyl ketone at mass ratio of 1:1, “IRGACURE 500” manufactured by Ciba Specialty Chemicals Corp.
(C) Isocyanate-based crosslinking agent: trimethylolpropane-modified tolylene diisocyanate (“CORONATE L” manufactured by Nippon Polyurethane Industry Co., Ltd.)
(D) Silane coupling agent: 3-glycidoxypropyltrimethoxysilane (“KBM-403” manufactured by Shin-Etsu Chemical Co., Ltd.)

### [Production of Composition for Forming UV Adhesive Layer]

A composition for forming a UV adhesive layer, having the following formulation, was prepared.

Composition for forming UV adhesive layer

| | |
|---|---|
| CEL2021P (manufactured by | 70 parts by mass |
| Daicel Corporation) | |
| 1,4-Butanediol diglycidyl ether | 20 parts by mass |
| 2-Ethylhexyl glycidyl ether | 10 parts by mass |
| CPI-100P | 2.25 parts by mass |

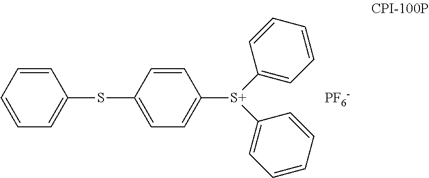

### [Production of Laminate CPAC1]

The above-described TAC film having the positive A plate F1 on the phase difference side and the above-described TAC film having the positive C plate H1 on the phase difference side were bonded to each other by irradiation with UV rays of 600 mJ/cm² using the above-described composition for forming a UV adhesive layer. A thickness of the UV adhesive layer was 3 μm. The surfaces bonded to each other with the UV adhesive layer were respectively subjected to a corona treatment. Next, the photo-alignment film E1 on the positive A plate F1 side and the cellulose acylate film A1 were removed to obtain a retardation plate AC1. The retardation plate AC1 had a layer configuration of the positive A plate F1, the UV adhesive layer, the positive C plate H1, the photo-alignment film G1, and the cellulose acylate film A1.

The above-described laminate CP1 on the oxygen-shielding layer D1 side was bonded to a low-reflection surface film CV-LC5 (manufactured by FUJIFILM Corporation) on a support side using the above-described pressure-sensitive adhesive layer N1. Next, only the cellulose acylate film A1 of the above-described laminate CP1 was removed, and the surface from which the film had been removed and the retardation plate AC1 on the positive A plate F1 side were bonded to each other using the above-described pressure-sensitive adhesive layer N1. Next, the photo-alignment film G1 on the positive C plate H1 side and the cellulose acylate film A1 included in the above-described retardation plate AC1 were removed, thereby producing a laminate CPAC1. At this time, the films were bonded to each other such that an angle between an absorption axis of the light absorption anisotropic film C1 included in the above-described laminate CPAC1 and a slow axis of the positive A-plate F1 was set to 45°. The laminate CPAC1 had a layer configuration of the low-reflection surface film CV-LC5, the pressure sensitive adhesive layer N1, the oxygen-shielding layer D1, the light absorption anisotropic film C1, the photo-alignment film B1, the pressure-sensitive adhesive layer N1, the positive A-plate F1, the UV adhesive layer, and the positive C plate H1.

GALAXY S5 (manufactured by Samsung Electronics Co., Ltd.) equipped with an organic EL display panel was disassembled, a touch panel provided with a circularly polarizing plate was peeled off from the organic EL display device, and a circularly polarizing plate was further peeled off from the touch panel, so that the organic EL display panel, the touch panel, and the circularly polarizing plate were isolated from each other. Subsequently, the isolated touch panel was bonded to the organic EL display panel again, and the laminate CPAC1 on the positive C plate H1 side, which had been produced above, was bonded onto the touch panel through the produced pressure-sensitive adhesive layer N1 such that air did not enter, thereby producing an organic EL display device.

### Example 2

A laminate and an organic EL display device were produced in the same manner as in Example 1, except that the heating temperature in the second heating step in a case of producing the light absorption anisotropic film was changed to 45° C.

### Example 3

A laminate and an organic EL display device were produced in the same manner as in Example 1, except that the following composition 2 for forming a light absorption anisotropic film was used instead of the composition 1 for forming a light absorption anisotropic film, and the heating temperature in the second heating step was changed to 45° C.

Formulation of composition 2 for forming
light absorption anisotropic film

| | |
|---|---|
| Dichroic substance Dye-C1 shown above | 0.15 parts by mass |
| Dichroic substance Dye-C2 shown above | 0.44 parts by mass |
| Dichroic substance Dye-M1 shown above | 0.14 parts by mass |
| Dichroic substance Dye-Y1 shown above | 0.25 parts by mass |
| Liquid crystal compound L-1 shown above | 3.27 parts by mass |
| Liquid crystal compound L-2 shown above | 1.40 parts by mass |
| Adhesion improver A-1 shown above | 0.06 parts by mass |
| Polymerization initiator IRGACURE | 0.18 parts by mass |
| OXE-02 (manufactured by BASF) | |
| Surfactant F-1 shown above | 0.01 parts by mass |
| Cyclopentanone | 91.75 parts by mass |
| Benzyl alcohol | 2.35 parts by mass |

### Example 4

A laminate and an organic EL display device were produced in the same manner as in Example 1, except that the following composition 3 for forming a light absorption anisotropic film was used instead of the composition 1 for forming a light absorption anisotropic film, and the heating temperature in the second heating step was changed to 45° C.

In addition, a phase transition temperature (temperature at the time of transition from a crystal state to a liquid crystal state) of the liquid crystal compound L-2 which was the liquid crystal compound was 75° C., which was 30° C. higher than the heating temperature (45° C.) in the second heating step.

Formulation of composition 3 for forming
light absorption anisotropic film

| | |
|---|---|
| Dichroic substance Dye-C1 shown above | 0.15 parts by mass |
| Dichroic substance Dye-C2 shown above | 0.44 parts by mass |
| Dichroic substance Dye-M1 shown above | 0.14 parts by mass |
| Dichroic substance Dye-Y1 shown above | 0.25 parts by mass |
| Liquid crystal compound L-2 shown above | 2.81 parts by mass |
| Adhesion improver A-1 shown above | 0.06 parts by mass |
| Polymerization initiator IRGACURE | 0.12 parts by mass |
| OXE-02 (manufactured by BASF) | |
| Surfactant F-1 shown above | 0.01 parts by mass |
| Cyclopentanone | 93.61 parts by mass |
| Benzyl alcohol | 2.40 parts by mass |

### Example 5

### [Formation of Alignment Film A]

After passing a long cellulose acylate film (TD80UL, manufactured by Fujifilm Corporation) through a dielectric heating roll at a temperature of 60° C. to raise the film surface temperature to 40° C., an alkaline solution having the following formulation was applied onto a band surface of the film using a bar coater at a coating amount of 14 ml/m², followed by heating to 110° C., and transportation under a steam type far-infrared heater manufactured by Noritake Company Limited for 10 seconds. Subsequently, pure water was applied onto the film at 3 ml/m² using the same bar coater. Next, the film was washed with water by a fountain coater and drained by an air knife three times, and then transported to a drying zone at 70° C. for 10 seconds and dried to produce a cellulose acylate film (thickness: 80 μm) subjected to an alkali saponification treatment.

Formulation of alkaline solution

| | | |
|---|---|---|
| Potassium hydroxide | 4.7 | parts by mass |
| Water | 15.8 | parts by mass |
| Isopropanol | 63.7 | parts by mass |
| Surfactant SF-1: | 1.0 | part by mass |
| C₁₄H₂₉O(CH₂CH₂O)₂₀H | | |
| Propylene glycol | 14.8 | parts by mass |

An alignment film coating liquid A having the following formulation was continuously applied onto the surface of the cellulose acylate film which had been subjected to the alkali saponification treatment with a #14 wire bar. Next, the coating film was dried with hot air at 60° C. for 60 seconds and further dried with hot air at 100° C. for 120 seconds to obtain an alignment film A (thickness: 0.5 μm).

Formulation of alignment film coating liquid A

| | |
|---|---|
| Polyvinyl alcohol-1 shown below | 10 parts by mass |
| Water | 371 parts by mass |
| Methanol | 119 parts by mass |
| Glutaraldehyde (crosslinking agent) | 0.5 parts by mass |
| Citric acid ester (manufactured | 0.175 parts by mass |
| by Sankyo Chemical Co., Ltd.) | |

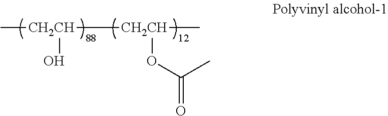

### [Production of Optically Anisotropic Layer Q]

The alignment film A produced above was continuously subjected to a rubbing treatment. In this case, a longitudinal direction of the elongated film was parallel to a transport direction, and an angle formed between the longitudinal direction of the film and a rotation axis of the rubbing roller was set to 45° (in a case where the width direction of the film was defined as 0°, the longitudinal direction of the film was defined as 90°, and the counterclockwise direction was expressed as a positive value with reference to the width direction of the film observed from the alignment film side, the rotation axis of the rubbing roller was) 45°.

The alignment film A subjected to the rubbing treatment was continuously coated with a coating liquid for an optically anisotropic layer Q containing a rod-like liquid crystal compound having the following formulation using a #3.4 wire bar. A transportation speed (V) of the film was 26 m/min. In order to dry the solvent of the coating liquid and to mature the alignment of the rod-like liquid crystal compound, the coating film on the alignment film was heated with hot air at 85° C. for 80 seconds, and irradiated with UV rays at 75° C. to fix the alignment of the liquid crystal compound, thereby producing an optically anisotropic layer Q. A thickness of the optically anisotropic layer Q was 1.2 μm. It was confirmed that the average tilt angle of the major axis of the rod-like liquid crystal compound with respect to the film surface was 0° and the liquid crystal compound was horizontally aligned with respect to the film surface. In addition, the angle of the slow axis was orthogonal to the rotation axis of the rubbing roller, and in a case where the width direction of the film was indicated by 0° (the longitudinal direction of the film was 90° and a counterclockwise direction was indicated by a positive value with reference to the width direction of the film observed from the optically anisotropic layer Q side), the angle of the slow axis was −45°. The optically anisotropic layer Q had an in-plane retardation of 142 nm at a wavelength of 550 nm, and the optically anisotropic layer Q exhibited forward wavelength dispersibility.

Formulation of coating liquid for optically anisotropic layer Q

| | |
|---|---|
| Mixture (A) of rod-like liquid crystal compounds | 100 parts by mass |
| Photopolymerization initiator (IRGACURE | 6 parts by mass |
| 907, manufactured by BASF) | |
| Fluorine-containing compound (F-2) | 0.20 parts by mass |
| Ethylene oxide-modified | 4 parts by mass |
| trimethylolpropane triacrylate | |
| Methyl ethyl ketone | 321 parts by mass |

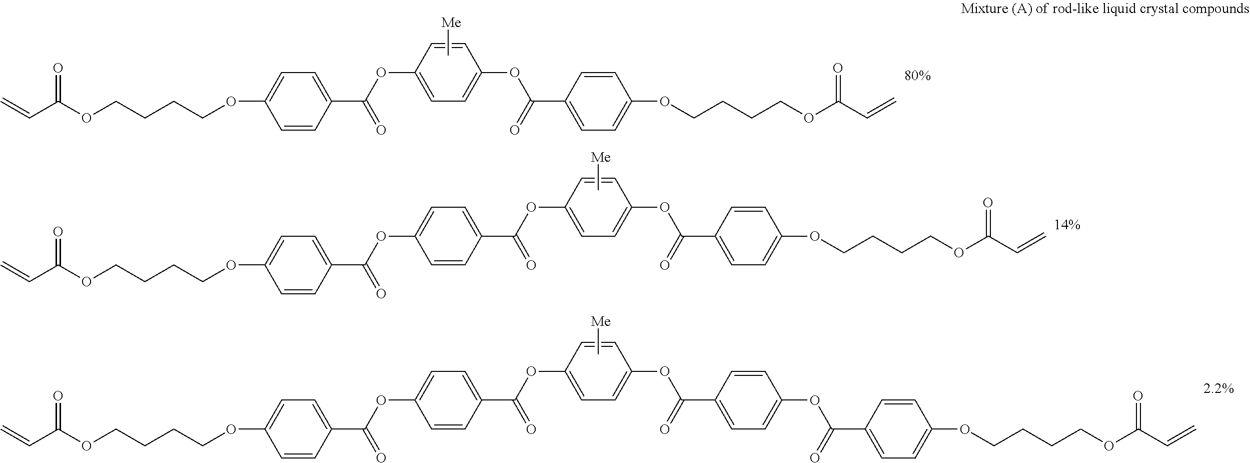

Fluorine-containing compound (F-2) (weight-average molecular weight: 16,400)

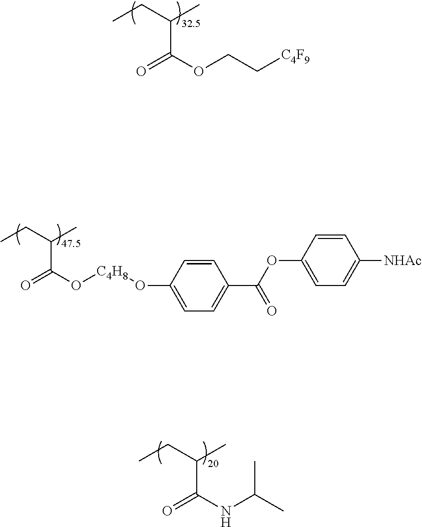

### [Production of Photo-Alignment Film B2]

The optically anisotropic layer Q was continuously coated with the above-described composition for forming a photo-alignment film using a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film, thereby obtaining an optically anisotropic film with a photo-alignment film. A film thickness of the photo-alignment film was 0.9 μm.

### [Production of Laminate X1]

A laminate X1 in which the cellulose acylate film, the alignment film A, the optically anisotropic layer Q, the photo-alignment film B2, the light absorption anisotropic film C1, and the oxygen-shielding layer D1 were formed in this order was obtained in the same manner as in Example 1, except that the triacetyl cellulose (TAC) film with a photo-alignment film was changed to the optically anisotropic film with a photo-alignment film.

### [Production of Laminate X2]

The above-described laminate X1 on the oxygen-shielding layer D1 side was bonded to a low-reflection surface film CV-LC5 (manufactured by FUJIFILM Corporation) on a support side using the above-described pressure-sensitive adhesive layer N1. Next, the cellulose acylate film and the alignment film A included in the above-described laminate X1 were removed to produce a laminate X2. The layer configuration of the laminate X2 was the low-reflection surface film CV-LC5, the pressure-sensitive adhesive layer N1, the oxygen-shielding layer D1, the light absorption anisotropic film C1, the photo-alignment film B2, and the optically anisotropic layer Q.

GALAXY S5 (manufactured by Samsung Electronics Co., Ltd.) equipped with an organic EL display panel was disassembled, a touch panel provided with a circularly polarizing plate was peeled off from the organic EL display device, and a circularly polarizing plate was further peeled off from the touch panel, so that the organic EL display panel, the touch panel, and the circularly polarizing plate were isolated from each other. Subsequently, the isolated touch panel was bonded to the organic EL display panel again, and the laminate X2 on the optically anisotropic layer Q side, which had been produced above, was bonded onto the touch panel through the produced pressure-sensitive adhesive layer N1 such that air did not enter, thereby producing an organic EL display device.

### Comparative Example 1

A laminate and an organic EL display device were produced in the same manner as in Example 1, except that the following composition 4 for forming a light absorption anisotropic film was used instead of the composition 1 for forming a light absorption anisotropic film, and the heating temperature in the second heating step was changed to 75° C.

Formulation of composition 4 for forming
light absorption anisotropic film

| | |
|---|---|
| Dichroic substance Dye-C1 shown above | 0.65 parts by mass |
| Dichroic substance Dye-M1 shown above | 0.15 parts by mass |
| Dichroic substance Dye-Y1 shown above | 0.52 parts by mass |
| Liquid crystal compound L-1 shown above | 2.50 parts by mass |
| Liquid crystal compound L-2 shown above | 1.50 parts by mass |
| Polymerization initiator IRGACURE | 0.17 parts by mass |
| OXE-02 (manufactured by BASF) | |
| Surfactant F-1 shown above | 0.01 parts by mass |
| Cyclopentanone | 92.14 parts by mass |
| Benzyl alcohol | 2.36 parts by mass |

### [Number of Associates]

By the above-described method, the cross section was observed for each of the light absorption anisotropic films of Examples and Comparative Example, the lengths of the major axes of 100 selected associates were measured, and the number Na of the associates A having a length of the major axis of less than 30 nm, the number Nb of the associates B having a length of the major axis of 30 nm or more and less than 60 nm, and the number Nc of the associates C having a length of the major axis of 60 nm or more were determined. The results are shown in Table 1.

### [Concentration of Dichroic Substance in Light Absorption Anisotropic Film]

A concentration (mg/cm³) of the dichroic substance in each of the light absorption anisotropic films of Examples and Comparative Example was measured by the above-described method. The results are shown in Table 1.

### [Δlog P]

The log P value of the dichroic substance and the log P value of the liquid crystal compound contained in each of the light absorption anisotropic films of Examples and Comparative Example were measured by the above-described methods, and the absolute value (Δlog P) of the difference between the log P value of the dichroic substance and the log P value of the liquid crystal compound was obtained. In a case where a plurality of dichroic substances or liquid crystal compounds were used, the maximum value among the absolute values of the differences calculated from the log P values of the respective compounds was adopted as the Δlog P. The results are shown in Table 1.

### [Evaluation Test]

### [Black Density]

Visibility and display quality of each of the organic EL display devices of Examples and Comparative Example were evaluated under bright light. Specifically, a display screen of the organic EL display device was set to black display, reflected light in a case where a fluorescent lamp was projected from the front was observed, and the black density was evaluated based on the following standard. The results are shown in Table 1.

### <Evaluation Standard>

A: it was black, no color-tinting was recognized at all, and the reflectivity was low.
B: coloration was slightly recognized, but the reflectivity was low.
C: coloration was slightly recognized, and the reflectivity was high.

### [Heat Resistance]

Each of the organic EL display devices of Examples and Comparative Example was aged for 500 hours in an environment of 85° C. and a relative humidity of less than 10% (heat resistance test). Thereafter, a display screen of the obtained organic EL display device was set to black display, reflected light in a case where a fluorescent lamp was projected from the front was observed, and the heat resistance was evaluated based on the following standard. The results are shown in Table 1.

### <Evaluation Standard>

A: compared to the evaluation results of the black density before the heat resistance test, the coloration was the same as before the heat resistance test, and the change in reflectivity was also the same.
B: compared to the evaluation results of the black density before the heat resistance test, the coloration was slightly increased, but the change in reflectivity was also the same.
C: compared to the evaluation results of the black density before the heat resistance test, the coloration was slightly increased, and the change in reflectivity was also increased.

TABLE 1

| | | | | | | Difference between phase | | |
|---|---|---|---|---|---|---|---|---|
| | | | | | | transition temperature of | | |
| | Associate of dichroic | | | Concentration of dichroic | | liquid crystal compound | | |
| | substance | | | substance in light | | and second heating | | |
| | Na | Nb | Nc | absorption anisotropic film | | temperature | Evaluation result | |
| | (number) | (number) | (number) | (mg/cm³) | Δlog P | (° C.) | Black density | Heat resistance |
| Example 1 | 9 | 88 | 3 | 250 | 6.3 | 30 | A | A |
| Example 2 | 20 | 79 | 1 | 250 | 6.3 | 40 | A | B |
| Example 3 | 23 | 51 | 26 | 170 | 6.3 | 40 | B | B |
| Example 4 | 16 | 54 | 30 | 250 | 4.0 | 30 | B | A |
| Example 5 | 9 | 88 | 3 | 250 | 6.3 | 30 | B | A |
| Comparative | 2 | 42 | 56 | 240 | 6.3 | 10 | C | A |
| Example 1 | | | | | | | | |

In Table 1, “Difference between phase transition temperature of liquid crystal compound and second heating temperature (° C.)” indicates a value obtained by subtracting the heating temperature (second heating temperature) of the second heating step from the phase transition temperature of the liquid crystal compound having the highest content among the liquid crystal compounds contained in the composition (temperature at the time of transition from a crystal state to a liquid crystal state).

As shown in Table 1, it was found that, in a case where a circularly polarizing plate obtained by combining a light absorption anisotropic film in which the number Nb of the associates B and the number Nc of the associates C satisfied the relationship of the expression (1) (Nb>Nc), and a λ/4 plate was applied to a display device, the black density was excellent (Examples).

In addition, from the comparison of Examples 1 to 4, it was found that, in a case where the light absorption anisotropic film in which the number Nb of the associates B and the number Nc of the associates C satisfied the relationship of the expression (2) (0.5×Nb>Nc) (Examples 1 and 2), the black density was more excellent.

In addition, from the comparison of Examples 1 to 4, it was found that, in a case where the light absorption anisotropic film in which the number Na of the associates A was less than 20 was used (Examples 1 and 4), the heat resistance was more excellent.

### Example 6

### [Production of Moth-Eye Film 1]

With regard to the description in paragraphs [0177] to [0210] of WO2018/180003A, a substrate HC-1 with a hard coat layer was changed a PMMA film, and bonded with a UV adhesive. As a result, a moth-eye film 1 having a configuration of a moth-eye layer/UV adhesive layer/PMMA film was obtained.

### (Production of Optical Laminate B0)

An optical laminate B0 was produced by the following procedure. A wideband dielectric multi-layer film (trade name: APF, 3M Company) was used as a linearly polarized light-reflective polarizer. The retardation plate AC1 was bonded to one surface of the APF with the pressure-sensitive adhesive layer N1, and the photo-alignment film G1 on the positive C plate H1 side and the cellulose acylate film A1 included in the retardation plate AC1 were peeled off. In this manner, an optical laminate B0 consisting of linearly polarized light-reflective polarizer (APF)/pressure-sensitive adhesive layer N1/positive A plate F1/UV adhesive layer/positive C plate was produced.

### [Production of Optical Laminate B1K10]

The APF side of the optical laminate B0 obtained above and the oxygen-shielding layer D1 side of the laminate X1 were bonded to each other with the acrylate-based pressure sensitive adhesive N1, and the cellulose acylate film and the alignment film A were removed. However, the APF and the light absorption anisotropic film C1 were laminated such that the transmission axis of the APF and the transmission axis of the light absorption anisotropic film C1 matched each other. Next, the pressure-sensitive adhesive layer N1 was provided on the positive C plate side. In this manner, an optical laminate D1 consisting of pressure-sensitive adhesive layer N1/positive C plate/UV adhesive layer/positive A plate F1/pressure-sensitive adhesive layer N1/linearly polarized light-reflective polarizer/pressure-sensitive adhesive layer N1/oxygen-shielding layer D1/light absorption anisotropic film C1/photo-alignment film B2/optically anisotropic layer Q was obtained.

### (Production of Optical Laminate B2K11 and Pancake Optical System)

The PMMA film side of the moth-eye film 1 was bonded to the optically anisotropic layer Q side of the above-described optical laminate D1 with the acrylate-based pressure sensitive adhesive N1. In this manner, an optical laminate D2 consisting of pressure-sensitive adhesive layer N1/positive C plate/UV adhesive layer/positive A plate F1/pressure-sensitive adhesive layer N1/linearly polarized light-reflective polarizer/pressure-sensitive adhesive layer N1/oxygen-shielding layer D1/light absorption anisotropic film C1/photo-alignment film B2/optically anisotropic layer Q/pressure-sensitive adhesive layer N1/PMMA film/UV adhesive layer/moth-eye layer was obtained. The above-described optical laminate D2 functions as a virtual reality (VR) application by using the optical laminate D2 instead of a wave plate 1005, a reflective type polarizer 1006, and an absorptive polarizer 1007 of a pancake optical system shown in FIG. 5 of WO2020/209354A.

### EXPLANATION OF REFERENCES

P: light absorption anisotropic film
M: molecule of (first dichroic substance)
O: molecule of (second dichroic substance)
L: molecule of (liquid crystal compound)
G: aggregate
w: width
a: angle

What is claimed is:

1. A light absorption anisotropic film comprising:
a liquid crystal compound; and
a dichroic substance,
wherein the dichroic substance forms an associate, and
in a case where, in a cross section of the light absorption anisotropic film observed with a scanning transmission electron microscope, 100 of the associates are selected, a number of associates B in which a length of a major axis is 30 nm or more and less than 60 nm is denoted by Nb, and a number of associates C in which a length of a major axis is 60 nm or more is denoted by Nc, a relationship between Nb and Nc satisfies the following expression (1),
$$Nb > Nc . \qquad ( 1 )$$

2. The light absorption anisotropic film according to claim 1,
wherein the relationship between Nb and Nc satisfies the following expression (2),
$$0.5 \times Nb > Nc . \qquad ( 2 )$$

3. The light absorption anisotropic film according to claim 1,
wherein, in a case where, in a cross section of the light absorption anisotropic film observed with a scanning transmission electron microscope, 100 of the associates are selected, a number of associates A in which a length of a major axis is less than 30 nm is denoted by Na, Na is 35 or less.

4. The light absorption anisotropic film according to claim 1,
wherein a concentration of the dichroic substance in the light absorption anisotropic film is 180 mg/cm³ or more.

5. The light absorption anisotropic film according to claim 1,
wherein an absolute value of a difference between a log P value of the liquid crystal compound and a log P value of the dichroic substance is 4.1 or more.

6. A manufacturing method of the light absorption anisotropic film according to claim 1, comprising:
a coating film-forming step of forming a coating film by applying a composition containing a liquid crystal compound, a dichroic substance, and a solvent;
a first heating step of heating the coating film at a temperature higher than a melting point of the dichroic substance;
a cooling step of cooling the coating film subjected to the first heating step; and
a second heating step of heating the coating film subjected to the cooling step at a temperature lower than a phase transition temperature of the liquid crystal compound from a crystal state to a liquid crystal state by 15° C. or higher.

7. A laminate comprising:
a base material; and
the light absorption anisotropic film according to claim 1, disposed on the base material.

8. The laminate according to claim 7, further comprising:
a λ/4 plate provided on the light absorption anisotropic film.

9. An image display device comprising:
the light absorption anisotropic film according to claim 1.

10. An image display device comprising:
the laminate according to claim 7.

11. The light absorption anisotropic film according to claim 2,
wherein, in a case where, in a cross section of the light absorption anisotropic film observed with a scanning transmission electron microscope, 100 of the associates are selected, a number of associates A in which a length of a major axis is less than 30 nm is denoted by Na, Na is 35 or less.

12. The light absorption anisotropic film according to claim 2,
wherein a concentration of the dichroic substance in the light absorption anisotropic film is 180 mg/cm³ or more.

13. The light absorption anisotropic film according to claim 2,
wherein an absolute value of a difference between a log P value of the liquid crystal compound and a log P value of the dichroic substance is 4.1 or more.

14. A manufacturing method of the light absorption anisotropic film according to claim 2, comprising:
a coating film-forming step of forming a coating film by applying a composition containing a liquid crystal compound, a dichroic substance, and a solvent;
a first heating step of heating the coating film at a temperature higher than a melting point of the dichroic substance;
a cooling step of cooling the coating film subjected to the first heating step; and
a second heating step of heating the coating film subjected to the cooling step at a temperature lower than a phase transition temperature of the liquid crystal compound from a crystal state to a liquid crystal state by 15° C. or higher.

15. A laminate comprising:
a base material; and
the light absorption anisotropic film according to claim 2, disposed on the base material.

16. The laminate according to claim 15, further comprising:
a λ/4 plate provided on the light absorption anisotropic film.

17. An image display device comprising:
the light absorption anisotropic film according to claim 2.

18. An image display device comprising:
the laminate according to claim 8.

19. The light absorption anisotropic film according to claim 4,
wherein a concentration of the dichroic substance in the light absorption anisotropic film is 180 mg/cm³ or more.

20. The light absorption anisotropic film according to claim 5,
wherein an absolute value of a difference between a log P value of the liquid crystal compound and a log P value of the dichroic substance is 4.1 or more.
